(19) United States
(12) Patent Application Publication
(10) Pub. No.: US 2024/0212754 A1
(43) Pub. Date: Jun. 27, 2024

(54) MEMORY DEVICE INCLUDING THREE DIMENSIONAL ARRAY STRUCTURE AND OPERATING METHOD THEREOF

(71) Applicant: SK hynix Inc., Gyeonggi-do (KR)

(72) Inventor: KyuSub YOON, Gyeonggi-do (KR)

(21) Appl. No.: 18/321,001

(22) Filed: May 22, 2023

(30) Foreign Application Priority Data
Dec. 22, 2022 (KR) 10-2022-0181566

(51) Int. Cl. G11C 16/04; G11C 16/20; G11C 16/26

(52) U.S. Cl. CPC G11C 16/0483; G11C 16/20; G11C 16/26

(57) ABSTRACT

A memory device comprises a memory cell array comprising multiple memory cells that are connected between multiple word lines, multiple bit lines, and K strings, and a controller configured to: perform, in a read operation on a first logical page of a selected physical page corresponding to a selected word line, the multiple bit lines and a selected string, a first channel-initializing operation on the selected string and first strings among unselected strings, and perform, in a read operation on a second logical page of the selected physical page, a second channel-initializing operation on the selected string and second strings among the unselected strings, the first and second strings partially overlapping each other, wherein K is a natural number equal to or greater than 2.

### CROSS-REFERENCE TO RELATED APPLICATION

This application claims priority under 35 U.S.C. § 119 to Korean Patent Application No. 10-2022-0181566 filed on Dec. 22, 2022, which is incorporated herein by reference in its entirety.

### BACKGROUND

### 1. Field

Various embodiments relate to a memory device, and particularly, to a memory device including a three-dimensional (3-D) array structure and an operating method of the memory device.

### 2. Discussion of the Related Art

Memory systems are storage devices embodied using a semiconductor such as silicon (Si), germanium (Ge), gallium arsenide (GaAs), indium phosphide (InP), or the like. The memory systems are classified into a volatile memory device and a nonvolatile memory device. The volatile memory device is a memory device in which data stored therein is lost when power supply is interrupted. Representative examples of the volatile memory device include a static RAM (SRAM), a dynamic RAM (DRAM), a synchronous DRAM (SDRAM), etc. The nonvolatile memory device is a memory device in which data stored therein is retained even when power supply is interrupted. Representative examples of the nonvolatile memory device include a read only memory (ROM), a programmable ROM (PROM), an electrically programmable ROM (EPROM), an electrically erasable programmable ROM (EEPROM), a flash memory, a phase-change random access memory (PRAM), a magnetic RAM (MRAM), a resistive RAM (RRAM), a ferroelectric RAM (FRAM), etc. Flash memories are chiefly classified into a NOR-type memory or a NAND-type memory.

A nonvolatile memory device may include a memory cell array in which data is stored and a controller for controlling program, read, and erase operations for the memory cell array.

In this case, the memory cell array may include multiple memory blocks. Each of the multiple memory blocks may include multiple memory cells. In particular, in the memory cell array of a nonvolatile memory device including a 3-D structure, multiple memory cells that are connected among multiple word lines, multiple bit lines, and multiple strings may have a form in which the multiple memory cells are stacked on a substrate. In this case, the multiple strings for connecting the stacked multiple memory cells may be formed perpendicularly from the substrate.

As the degree of integration of nonvolatile memory devices including a 3-D structure is increased, the number of strings that are included in the memory cell array is increased. Accordingly, an electrical defect may occur between adjacent strings, among the multiple strings, as the interval between the adjacent strings is narrowed.

### SUMMARY

Various embodiments of the present disclosure are directed to providing a memory device capable of suppressing hot carrier injection which may occur in an unselected string when a read operation is performed on a selected string, among multiple strings that are included in a memory cell array, and an operating method of the memory device.

The problems to be solved by the present disclosure are not limited to the above-mentioned problems, and the other unmentioned problems will be clearly understood from the following description by those skilled in the art.

An aspect of an embodiment of the present disclosure, a memory device may include: a memory cell array comprising multiple memory cells that are connected between multiple word lines, multiple bit lines, and K strings; and a controller configured to: perform, in a read operation on a first logical page of a selected physical page corresponding to a selected word line, the multiple bit lines and a selected string, a first channel-initializing operation on the selected string and first strings among unselected strings, and perform, in a read operation on a second logical page of the selected physical page, a second channel-initializing operation on the selected string and second strings among the unselected strings, the first and second strings partially overlapping each other. K may be a natural number equal to or greater than 2.

An aspect of an embodiment of the present disclosure, an operating method of a memory device, may include: a selection operation of selecting first and second strings from unselected strings if first and second logical pages correspond to a selected physical page corresponding to a selected word line, multiple bit lines and a selected string, the first and second strings partially overlapping each other; a first initialization operation of performing a channel-initializing operation on the selected string and the first strings in a read operation on the first logical page; and a second initialization operation of performing a channel-initializing operation on the selected string and the second strings in a read operation for the second logical page.

An aspect of an embodiment of the present disclosure, an operating method of a memory device including memory cell strings configuring at least a physical page, the operating method may include: selecting one from the memory cell strings; determining first to third groups of unselected ones from the memory cell strings, the third group being an intersection of the first and second groups; performing a channel-initializing operation on the selected string and the first group during a read operation on a first logical page of the physical page; and performing the channel-initializing operation on the selected string and the second group during a read operation on a second logical page of the physical page. The determining may include adjusting, based on a physical location of the selected string, a number of the unselected memory cell strings belonging to the third group.

In the present technology, a channel-initializing operation can be performed on some unselected strings together with a selected string, among multiple strings that are included in a memory cell array, in order to suppress hot carrier injection which may occur in the unselected string when a read operation is performed on the selected string.

In particular, in the present technology, when a memory cell that is included in a memory cell array is a multi-level cell in which 2-bit or more data is stored, the types of some unselected strings on which a channel-initializing operation is performed, along with a selected string, may be set to be different from each other.

Accordingly, it is possible to improve the reliability of a read operation while minimizing the time taken to perform a channel-initializing operation that is included in the read operation.

### BRIEF DESCRIPTION OF THE DRAWINGS

FIG. 1 is a diagram for describing an example of a method of controlling a channel-initializing operation that is included in a read operation in a memory device according to an embodiment of the present disclosure.

FIGS. 2A to 2D are diagrams for describing a method of controlling a channel-initializing operation for a memory cell array including a three-dimensional (3-D) structure in which six strings are connected to one bit line according to an embodiment of the present disclosure.

FIGS. 3A to 3D are diagrams for describing a method of controlling a channel-initializing operation for a memory cell array including a 3-D structure in which eight strings are connected to one bit line according to an embodiment of the present disclosure.

FIGS. 4A to 4D are diagrams for describing a method of controlling a channel-initializing operation for a memory cell array including a 3-D structure in which sixteen strings are connected to one bit line according to an embodiment of the present disclosure.

FIG. 5 is a diagram for describing a detailed configuration of the memory device according to an embodiment of the present disclosure, which is disclosed in FIG. 1.

FIG. 6 is a diagram for describing a circuit configuration of a string in the memory cell array including the 3-D structure in which six strings are connected to one bit line, which is disclosed in FIGS. 1 and 2A according to an embodiment of the present disclosure.

FIG. 7 is a diagram for describing a cross-sectional structure of one of the six strings illustrated in FIG. 6 according to an embodiment of the present disclosure.

FIG. 8 is a diagram for describing a layout structure of a memory cell illustrated in FIG. 7 according to an embodiment of the present disclosure.

### DETAILED DESCRIPTION

Various embodiments of the present disclosure are described below with reference to the accompanying drawings. Elements and features of this disclosure, however, may be configured or arranged differently to form other embodiments, which may be variations of any of the disclosed embodiments.

Herein, an item of data, a data item, a data entry or an entry of data may be a sequence of bits. For example, the data item may include the contents of a file, a portion of the file, a page in memory, an object in an object-oriented program, a digital message, a digital scanned image, a part of a video or audio signal, metadata or any other entity which can be represented by a sequence of bits. According to an embodiment, the data item may include a discrete object. According to another embodiment, the data item may include a unit of information within a transmission packet between two different components.

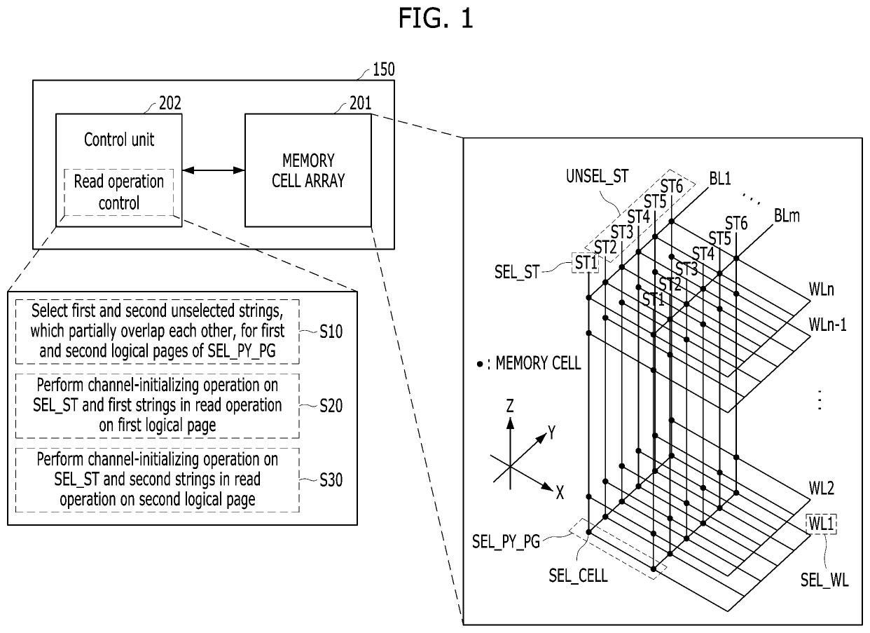

Referring to FIG. 1, a memory device 150 according to an embodiment of the present disclosure may include a memory cell array 201 and a controller 202.

In this case, the memory cell array 201 may include a 3-D structure. For example, the memory cell array 201 may include multiple memory cells that are stacked on a substrate. Accordingly, the multiple memory cells may be arranged in a +X direction, a +Y direction, and a +Z direction.

More specifically, the memory cell array 201 may include multiple memory cells MEMORY CELL that are connected among multiple word lines WL<1:n> that are arranged in a Z direction, multiple bit lines BL<1:m> that are arranged in an X direction, and K strings that are arranged in a Y direction. In this case, K may be a natural number equal to or greater than 2.

Memory cells that are connected between a word line SEL_WL that has been selected for a read or program operation, among the multiple word lines WL<1:n>, the multiple bit lines BL<1:m>, and the K strings may constitute K physical pages. In this case, it may be seen that the number of physical pages and the number of strings that are connected to the selected word line SEL_WL are identically K. That is, it may be seen that memory cells that are connected in the X direction between the selected word line SEL_WL and one string constitute one physical page.

Accordingly, memory cells SEL_CELL that have been selected by the word line SEL_WL that has been selected for the read or program operation, the multiple bit lines BL<1:m>, and one string SEL_ST that has been selected for the read or program operation, among the K strings, may constitute one physical page SEL_PY_PG that has been selected for the read or program operation. Furthermore, memory cells that are connected between the selected word line SEL_WL, the multiple bit lines BL<1:m>, and (K−1) unselected strings UNSEL_ST that have not been selected for the read or program operation, among the K strings, may constitute (K−1) unselected physical pages.

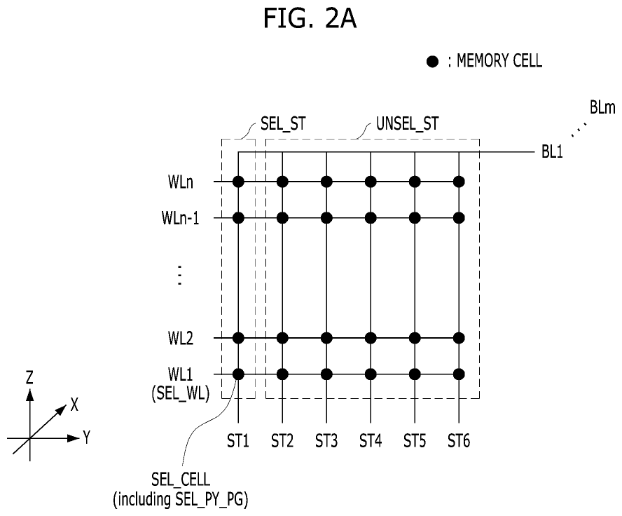

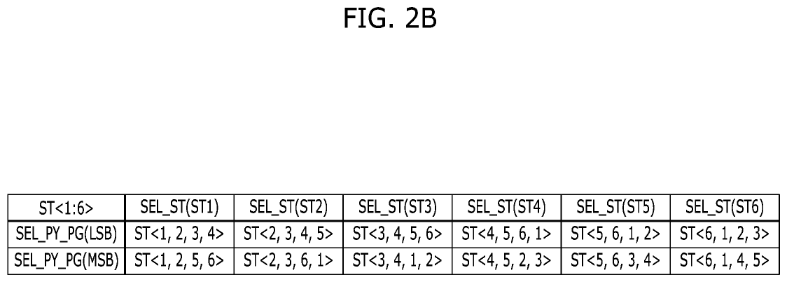

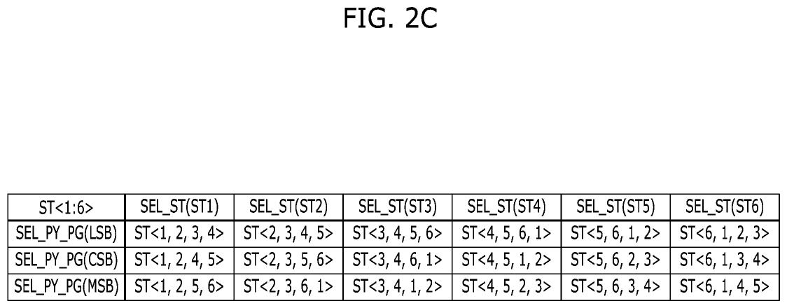

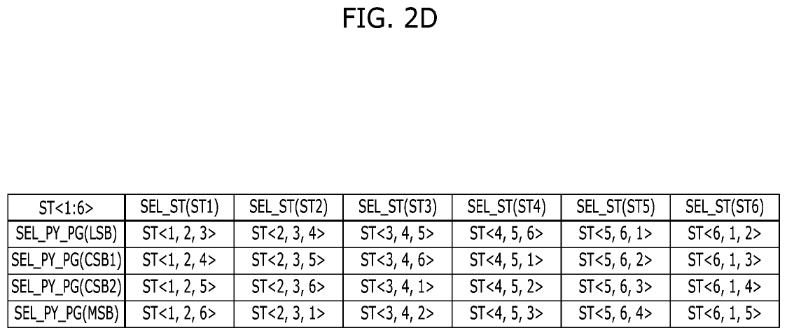

According to an embodiment, referring to FIGS. 1 and 2A, the memory cell array 201 may include the multiple word lines WL<1:n> that are arranged in the Z direction, the multiple bit lines BL<1:m> that are arranged in the X direction, and the multiple memory cells MEMORY CELL that are arranged in the Y direction and that are connected between six strings ST<1:6>. That is, as disclosed in FIGS. 1 and 2A, K is 6. Accordingly, memory cells SEL_CELL that have been selected by one selected word line SEL_WL, WL1, the multiple bit lines BL<1:m>, and the one selected string SEL_ST, ST1 may constitute one selected physical page SEL_PY_PG. Furthermore, memory cells that are connected between one selected word line SEL_WL, WL1, the multiple bit lines BL<1:m>, and five unselected strings UNSEL_ST, ST<2:6> may constitute five unselected physical pages.

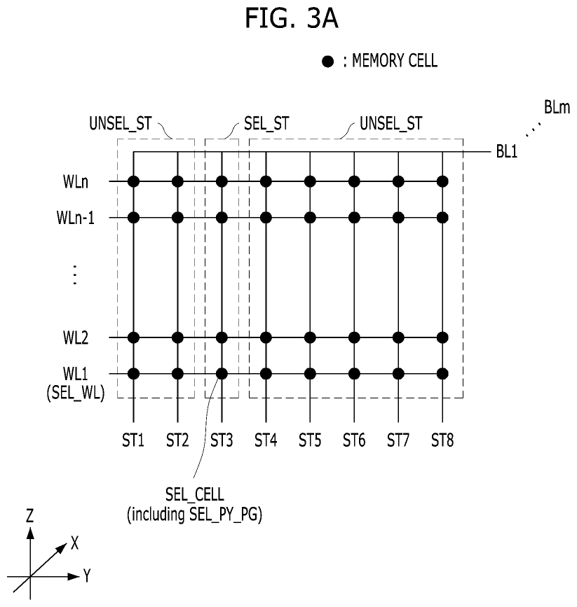

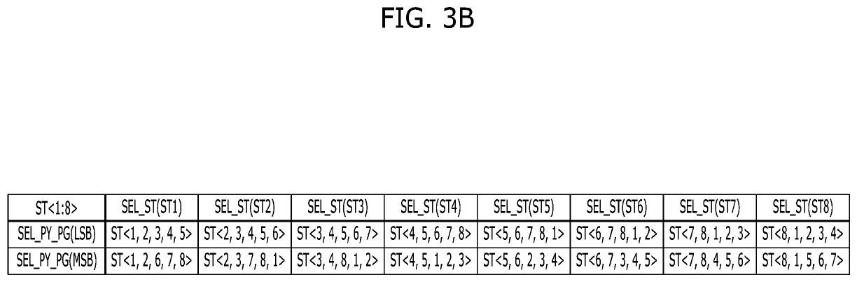

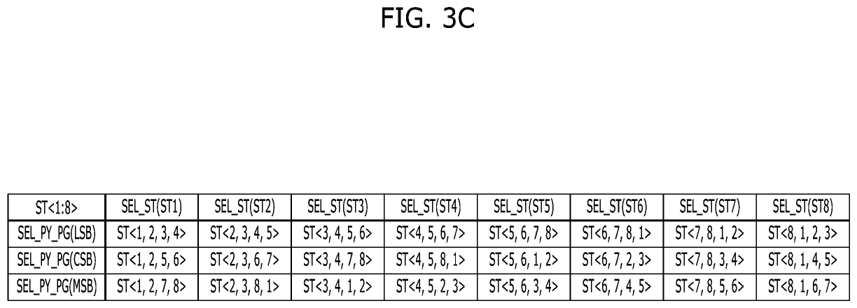

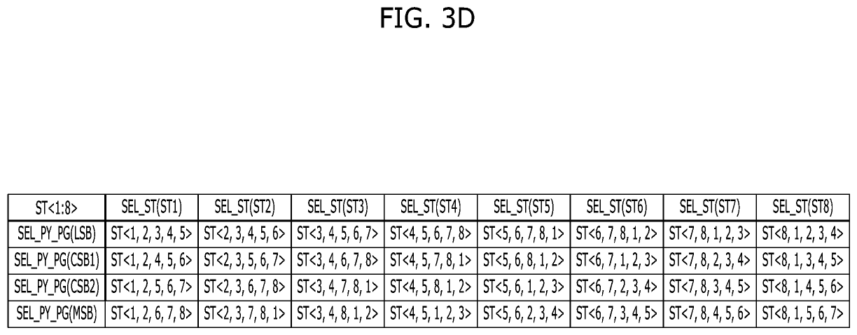

According to an embodiment, referring to FIG. 3A, the memory cell array 201 may include multiple memory cells MEMORY CELL that are connected between the multiple word lines WL<1:n> that are arranged in the Z direction, the multiple bit lines BL<1:m> that are arranged in the X direction, and eight strings ST<1:8> that are arranged in the Y direction. That is, as disclosed in FIG. 3A, K is 8. Accordingly, memory cells SEL_CELL that have been selected by one selected word line SEL_WL, WL1, the multiple bit lines BL<1:m>, and one selected string SEL_ST, ST3 may constitute one selected physical page SEL_PY_PG. Furthermore, memory cells that are connected between the one selected word line SEL_WL, the multiple bit lines BL<1:m>, and seven unselected strings UNSEL_ST, ST<1, 2, 4, 5, 6, 7, 8> may constitute seven unselected physical pages.

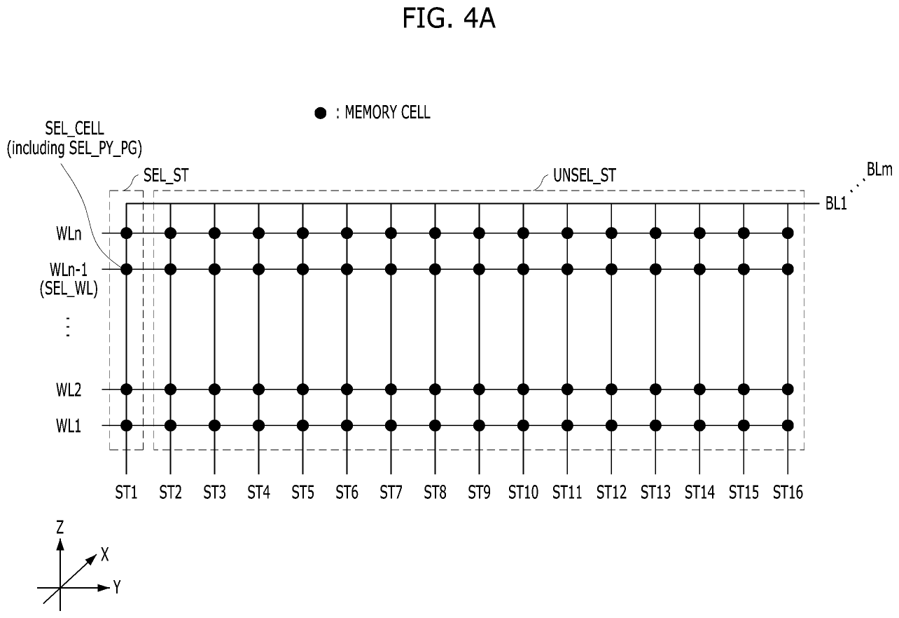

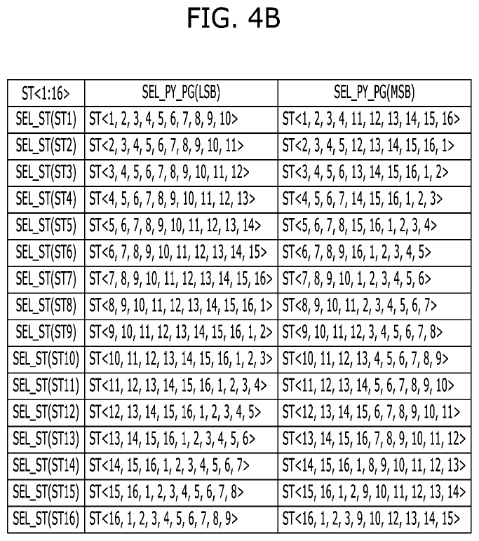

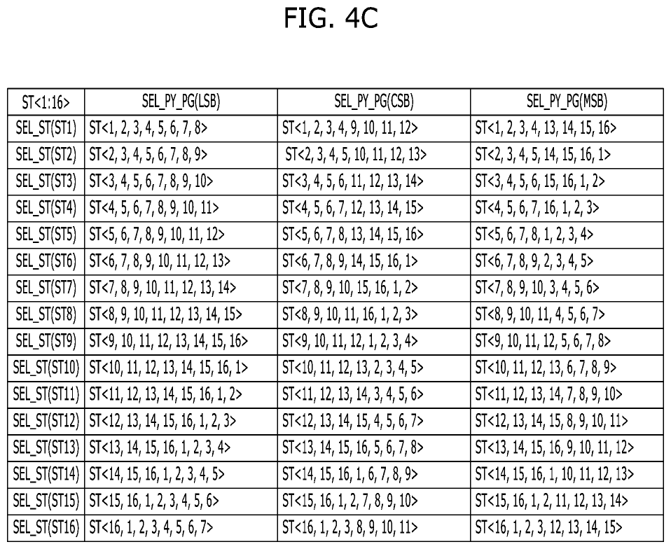

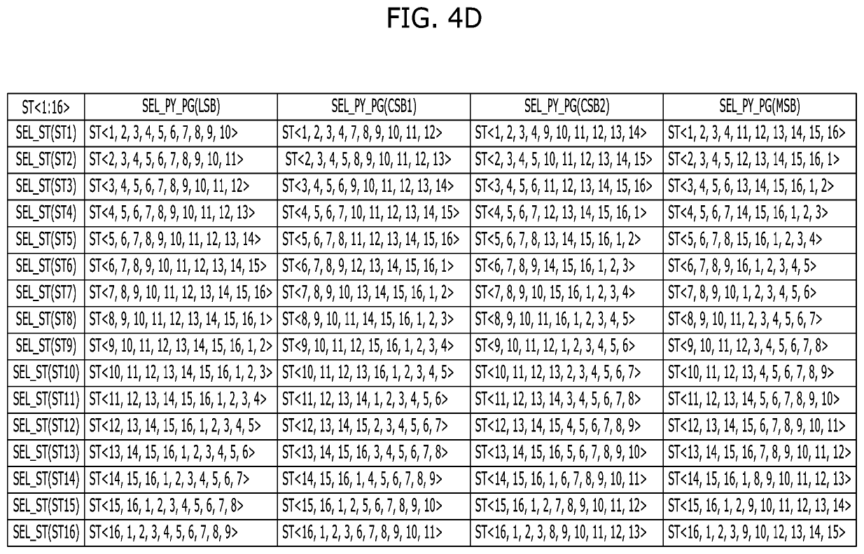

According to an embodiment, referring to FIG. 4A, the memory cell array 201 may include multiple memory cells MEMORY CELL that are connected between the multiple word lines WL<1:n> that are arranged in the Z direction, the multiple bit lines BL<1:m> that are arranged in the X direction, and sixteen strings ST<1:16> that are arranged in the Y direction. That is, as disclosed in FIG. 4A, K is 16. Accordingly, memory cells SEL_CELL that have been selected by one selected word line SEL_WL, WLn-1, the multiple bit lines BL<1:m>, and one selected string SEL_ST, ST1 may constitute one selected physical page SEL_PY_PG. Furthermore, memory cells that are connected between the one selected word line SEL_WL, WLn-1, the multiple bit lines BL<1:m>, and fifteen unselected strings UNSEL_ST, ST<2:16> may constitute fifteen unselected physical pages.

The selected memory cells SEL_CELL configuring the selected physical page SEL_PY_PG may be programmed in various ways, and a read operation for the selected memory cells SEL_CELL may also vary depending on a program method. For example, a program or read operation may be divided into a single level cell method or a multi-level cell method based on the number of bits of data that is stored in one memory cell. The single level cell method may be a method of storing 1-bit data in one memory cell. The multi-level cell method may be a method of storing 2-bit or more data in one memory cell. The multi-level cell method may be divided into a triple level cell method or a quad level cell method based on the number of bits of data that is stored in one memory cell. The triple level cell method may be a method of storing 3-bit data in one memory cell. The quad level cell method may be a method of storing 4-bit data in one memory cell. Accordingly, a term, such as the multi-level cell method, may be defined as a method of storing 2-bit or more data in one memory cell by terms, such as the triple level cell method and the quad level cell method. In addition, a program or read operation may be performed in various ways in which 5-bit or more data is stored in one memory cell.

A read operation may be performed in a way corresponding to a program method. For example, when memory cells are programmed by using the triple level cell method, a read operation may also be performed by using the triple level cell method. As another embodiment, when memory cells are programmed by using the quad level cell method, a read operation may also be performed by using the quad level cell method.

Referring to FIG. 1, the control unit 202 may control a read operation of reading data from a selected region of the memory cell array 201. That is, the control unit 202 may read data stored in selected memory cells SEL_CELL configuring the physical page SEL_PY_PG that has been selected by the selected word line SEL_WL, the multiple bit lines BL<1:m>, and the selected string SEL_ST. In particular, if the selected memory cells SEL_CELL configuring the selected physical page SEL_PY_PG are memory cells in each of which 2-bit or more data is stored, the control unit 202 may adjust a method of controlling a channel-initializing operation in a read operation for the selected physical page SEL_PY_PG, based on the bit data read from 2-bit or more data stored in the selected memory cells SEL_CELL.

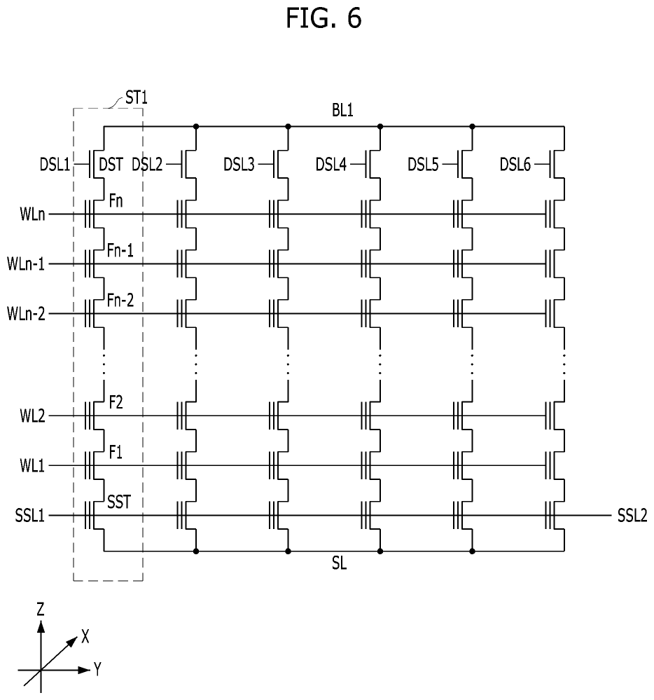

For reference, the channel-initializing operation may be an operation of initializing a channel by discharging the channel in order to prevent hot carrier injection from occurring in K string channels. For the detailed contents of the channel-initializing operation, reference may be made to descriptions related to FIGS. 6 to 8 disclosed below.

### In the Case of a Multi-Level Cell

Referring to FIGS. 2B, 3B, and 4B along with FIG. 1, it may be seen that if the selected memory cells SEL_CELL configuring the selected physical page SEL_PY_PG are multi-level cells in each of which 2-bit data is stored, a method of controlling a channel-initializing operation in a read operation for a first logical page LSB and a method of controlling a channel-initializing operation in a read operation for a second logical page MSB are different.

Specifically, if the first logical page LSB and the second logical page MSB correspond to the physical page SEL_PY_PG that has been selected by the selected word line SEL_WL, the multiple bit lines BL<1:m>, and the selected string SEL_ST, the control unit 202 may select L first strings of the (K−1) unselected strings UNSEL_ST except the selected string SEL_ST, among the K strings, and L second strings some of which overlap the first strings and the others of which do not overlap the first strings (S10). That is, the first and second strings may have an intersection therebetween and a string within the intersection may belong to both the first and second strings. In this case, K may be a natural number equal to or greater than 2, and L may be a natural number less than K−1.

Furthermore, in the read operation for the first logical page LSB, the control unit 202 may perform a channel-initializing operation on one selected string SEL_ST, among the K strings, and the L first strings (S20). That is, in the channel-initializing operation that is included in the read operation for the first logical page LSB, the control unit 202 may discharge the channel film of the one selected string SEL_ST, among the K strings, by connecting the channel film to a ground voltage stage, may discharge the channel films of the L first strings, among the (K−1) unselected strings UNSEL_ST, by connecting the channel films to the ground voltage stage, and may isolate, from the ground voltage stage, the channel films of the remaining unselected strings except the L first strings, among the (K−1) unselected strings UNSEL_ST.

Furthermore, in the read operation for the second logical page MSB, the control unit 202 may perform a channel-initializing operation on the one selected string SEL_ST, among the K strings, and the L second strings (S30). That is, in the channel-initializing operation that is included in the read operation for the second logical page MSB, the control unit 202 may discharge the channel film of the one selected string SEL_ST, among the K strings, by connecting the channel film to the ground voltage stage, may discharge the channel films of the L second strings, among the (K−1) unselected strings UNSEL_ST, by connecting the channel films to the ground voltage stage, and may isolate, from the ground voltage stage, the channel films of the remaining unselected strings except the L second strings, among the (K−1) unselected strings UNSEL_ST.

In this case, it may be seen that each of the number of first strings and the number of second strings the channels of which are initialized through the channel-initializing operation is less than the number of (K−1) unselected strings UNSEL_ST because L is the natural number less than K−1.

Furthermore, the control unit 202 may set a number “(L+1)” as a number “K/2 or more”. That is, in one channel-initializing operation that is performed on one of the first and second strings, the control unit 202 may initialize a channel corresponding to half (K/2) or more of the K strings.

Furthermore, if the first logical page LSB and the second logical page MSB correspond to the selected physical page SEL_PY_PG, when the channel-initializing operation is performed on each of the first and second strings once, that is, when the two channel-initializing operations are performed on the first and second strings, the control unit 202 may properly select the first string and the second string so that at least one channel-initializing operation is performed on each of the K strings. That is, the control unit 202 may properly select some strings that overlap each other between the first and second strings and the other strings that do not overlap each other between the first and second strings, so that the at least one channel-initializing operation is performed on each of the K strings when the channel-initializing operation is performed on each of the first and second strings once.

Furthermore, the control unit 202 may adjust a number of the strings that overlap each other between the first and second strings, based on the physical location of the selected string SEL_ST among the K strings. Furthermore, the control unit 202 may adjust the other strings that do not overlap each other between the first and second strings, based on the physical location of the selected string SEL_ST among the K strings.

A detailed embodiment is described as follows with reference to FIGS. 1 to 2B.

First, K is 6 in the description related to FIGS. 1 and 2A. Accordingly, in the following description, K is 6 and L is 3.

Referring to FIG. 2B, it may be seen that a change in the physical location of a string SEL_ST that has been selected as a read target, among the six strings ST<1:6>, is divided as a column, and two logical pages LSB and MSB of a physical page SEL_PY_PG that has been selected as a read target are divided as a row.

First, when a physical location of the string SEL_ST that has been selected as the read target is No. 1 (ST1), the control unit 202 may select, as first strings, the strings ST<2, 3, 4> having physical locations of Nos. 2, 3, and 4, respectively, among the five unselected strings UNSEL_ST, ST<2:6>, along with the No. 1 string ST1 that is a string SEL_ST that has been selected for a read operation for the first logical page LSB. Accordingly, in the read operation for the first logical page LSB, the control unit 202 may perform a channel-initializing operation on the Nos. 1 to 4 strings ST<1, 2, 3, 4>. That is, in the read operation for the first logical page LSB, the control unit 202 may perform the channel-initializing operation on the four strings ST<1, 2, 3, 4>, that is, half or more of the six strings ST<1:6>. Furthermore, in the read operation for the first logical page LSB, the control unit 202 may perform the channel-initializing operation on only the three strings ST<2, 3, 4>, that is, some of the five unselected strings UNSEL_ST, ST<2:6>.

Furthermore, the control unit 202 may select, as second strings, the strings ST<2, 5, 6> having physical locations of Nos. 2, 5, and 6, respectively, among the five unselected strings UNSEL_ST, ST<2:6>, along with the No. 1 string ST1 that is a string SEL_ST that has been selected for a read operation for the second logical page MSB. Accordingly, in the read operation for the second logical page MSB, the control unit 202 may perform a channel-initializing operation on the Nos. 1, 2, 5, and 6 strings ST<1, 2, 5, 6>. That is, in the read operation for the second logical page MSB, the control unit 202 may perform the channel-initializing operation on the four strings ST<1, 2, 5, 6>, that is, half or more of the six strings ST<1:6>. Furthermore, in the read operation for the second logical page MSB, the control unit 202 may perform the channel-initializing operation on only the three strings ST<2, 5, 6>, that is, some of the five unselected strings UNSEL_ST, ST<2:6>.

Furthermore, when the strings ST<2, 5, 6> that have been selected as the second strings are compared with the strings ST<2, 3, 4> that have been selected as the first strings, respectively, it may be seen that some strings ST2 overlap each other and some other strings ST<3, 4> do not overlap the strings ST<5, 6>. Furthermore, when the strings ST<2, 3, 4> that have been selected as the first strings are compared with the strings ST<2, 5, 6> that have been selected as the second strings, respectively, it may be seen that some strings ST2 overlap each other and some other strings ST<5, 6>do not overlap the strings ST<3, 4>. Furthermore, it may be seen that if all of the No. 1 string ST1 that is the string SEL_ST that has been selected for the read operation, the strings ST<2, 3, 4> that have been selected as the first strings, and the strings ST<2, 5, 6> that have been selected as the second strings are combined, each of the six strings ST<1:6> is included at least once. Accordingly, it may be seen that when each of the channel-initializing operation that is included in the read operation for the first logical page LSB and the channel-initializing operation that is included in the read operation for the second logical page MSB is performed once, at least one channel-initializing operation is performed on each of the six strings ST<1:6>.

Furthermore, when a physical location of the string SEL_ST that has been selected as a read target is No. 2 (ST2), the control unit 202 may select, as first strings, the strings ST<3, 4, 5> having physical locations of Nos. 3, 4, and 5, respectively, among the five unselected strings UNSEL_ST, ST<1, 3, 4, 5, 6>, along with the No. 2 string ST2 that is a string SEL_ST that has been selected for a read operation for the first logical page LSB. Accordingly, in the read operation for the first logical page LSB, the control unit 202 may perform a channel-initializing operation on the Nos. 2 to 5 strings ST<2, 3, 4, 5>. That is, in the read operation for the first logical page LSB, the control unit 202 may perform the channel-initializing operation on the four strings ST<2, 3, 4, 5>, that is, half or more of the six strings ST<1:6>. Furthermore, in the read operation for the first logical page LSB, the control unit 202 may perform the channel-initializing operation on only the three strings ST<3, 4, 5>, that is, some of the five unselected strings UNSEL_ST, ST<1, 3, 4, 5, 6>.

Furthermore, the control unit 202 may select, as second strings, the strings ST<3, 6, 1> having physical locations of Nos. 3, 6, and 1, respectively, among the five unselected strings UNSEL_ST, ST<1, 3, 4, 5, 6>, along with the No. 2 string ST2 that is a string SEL_ST that has been selected for a read operation for the second logical page MSB. Accordingly, in the read operation for the second logical page MSB, the control unit 202 may perform a channel-initializing operation on the Nos. 2, 3, 6, and 1 strings ST<2, 3, 6, 1>. That is, in the read operation for the second logical page MSB, the control unit 202 may perform the channel-initializing operation on the four strings ST<2, 3, 6, 1>, that is, half or more of the six strings ST<1:6>. Furthermore, in the read operation for the second logical page MSB, the control unit 202 may perform the channel-initializing operation on only the three strings ST<3, 6, 1>, that is, some of the five unselected strings UNSEL_ST, ST<1, 3, 4, 5, 6>.

Furthermore, when the strings ST<3, 6, 1> that have been selected as the second strings are compared with the strings ST<3, 4, 5> that have been selected as the first strings, respectively, it may be seen that some strings ST3 overlap each other and some other strings ST<4, 5> do not overlap the strings ST<6, 1>. Furthermore, when the strings ST<3, 4, 5> that have been selected as the first strings are compared with the strings ST<3, 6, 1> that have been selected as the second strings, respectively, it may be seen that some strings ST3 overlap each other and some other strings ST<6, 1> do not overlap the strings ST<4, 5>. Furthermore, it may be seen that if all of the No. 2 string ST2 that is the string SEL_ST that has been selected for the read operation, the strings ST<3, 4, 5> that have been selected as the first strings, and the strings ST<3, 6, 1> that have been selected as the second strings are combined, each of the six strings ST<1:6> is included at least once. Accordingly, it may be seen that when each of the channel-initializing operation that is included in the read operation for the first logical page LSB and the channel-initializing operation that is included in the read operation for the second logical page MSB is performed once, at least one channel-initializing operation is performed on each of the six strings ST<1:6>.

As in the aforementioned embodiment, when a physical location of a string SEL_ST that has been selected as a read target is No. 1 (ST1), it may be seen that strings that have been selected as first strings are ST<2, 3, 4>, strings that have been selected as second strings are ST<2, 5, 6>, some strings that overlap each other are ST2, and strings that do not overlap each other are ST<3, 4 or 5, 6>. In contrast, when the physical location of the string SEL_ST that has been selected as the read target is No. 2 (ST2), it may be seen that strings that have been selected as first strings are ST<3, 4, 5>, strings that have been selected as second strings are ST<3, 6, 1>, some strings that overlap each other are ST3, and strings that do not overlap each other are ST<4, 5 or 6, 1>. That is, it may be seen that strings that overlap each other between the first string and the second string are changed into one of ST2 and ST3 depending on whether the physical location of the selected string SEL_ST is the No. 1 (ST1) or the No. 2 (ST2). Furthermore, it may be seen that strings that do not overlap each other between the first string and the second string are changed into one of ST<3, 4 or 5, 6> and ST<4, 5 or 6, 1> depending on whether the physical location of the selected string SEL_ST is the No. 1 (ST1) or the No. 2 (ST2).

In the aforementioned embodiment, in the state in which the first logical page LSB and the second logical page MSB correspond to the selected physical page SEL_PY_PG, the contents that have been described with respect to the case in which the physical location of the string SEL_ST that has been selected as the read target is the No. 1 (ST1) and the contents that have been described with respect to the case in which the physical location of the string SEL_ST that has been selected as the read target is the No. 2 (ST2) may also be identically applied to each of cases in which the physical locations of selected strings SEL_ST are Nos. 3 to 6 (ST<3, 4, 5, 6>). Accordingly, for the detailed contents of the strings ST<3, 4, 5, 6>, reference may be made to FIG. 2B.

A detailed embodiment is described as follows with reference to FIGS. 3A and 3B.

First, in the description related to FIG. 3A, K is 8. Accordingly, in the following description, K is 8 and L is 4.

Referring to FIG. 3B, it may be seen that a change in the physical location of a string SEL_ST that has been selected as a read target, among the eight strings ST<1:8>, is divided as a column and two logical pages LSB and MSB corresponding to a physical page SEL_PY_PG that has been selected as a read target are divided as a row.

First, when a physical location of the string SEL_ST that has been selected as the read target is No. 3 (ST3), the control unit 202 may select, as first strings, the strings ST<4, 5, 6, 7> having physical locations of Nos. 4, 5, 6, and 7, respectively, among the seven unselected strings UNSEL_ST, ST<1, 2, 4, 5, 6, 7, 8>, along with the No. 3 string ST3 that is a string SEL_ST that has been selected for a read operation for the first logical page LSB. Accordingly, in the read operation for the first logical page LSB, the control unit 202 may perform a channel-initializing operation on the Nos. 3 to 7 strings ST<3, 4, 5, 6, 7>. That is, in the read operation for the first logical page LSB, the control unit 202 may perform the channel-initializing operation on the five strings ST<3, 4, 5, 6, 7>, that is, half or more of the eight strings ST<1:8>. Furthermore, in the read operation for the first logical page LSB, the control unit 202 may perform the channel-initializing operation on only the four strings ST<4, 5, 6, 7>, that is, some of the seven unselected strings UNSEL_ST, ST<1, 2, 4, 5, 6, 7, 8>.

Furthermore, the control unit 202 may select, as second strings, the strings ST<4, 8, 1, 2>having physical locations of Nos. 4, 8, 1, and 2, respectively, among the seven unselected strings UNSEL_ST, ST<1, 2, 4, 5, 6, 7, 8>, along with the No. 3 string ST3 that is a string SEL_ST that has been selected for a read operation for the second logical page MSB. Accordingly, in the read operation for the second logical page MSB, the control unit 202 may perform a channel-initializing operation on the Nos. 3, 4, 8, 1, and 2 strings ST<3, 4, 8, 1, 2>. That is, in the read operation for the second logical page MSB, the control unit 202 may perform the channel-initializing operation on the five strings ST<3, 4, 8, 1, 2>, that is, half or more of the eight strings ST<1:8>. Furthermore, in the read operation for the second logical page MSB, the control unit 202 may perform the channel-initializing operation on only the four strings ST<4, 8, 1, 2>, that is, some of the seven unselected strings UNSEL_ST, ST<1, 2, 4, 5, 6, 7, 8>.

Furthermore, when the strings ST<4, 8, 1, 2> that have been selected as the second strings are compared with the strings ST<4, 5, 6, 7> that have been selected as the first strings, respectively, it may be seen that some strings ST4 overlap each other and some other strings ST<5, 6, 7> do not overlap the strings ST<8, 1, 2>. Furthermore, when the strings ST<4, 5, 6, 7> that have been selected as the first strings are compared with the strings ST<4, 8, 1, 2> that have been selected as the second strings, it may be seen that some strings ST4 overlap each other and some other strings ST<8, 1, 2> do not overlap the strings ST<5, 6, 7>. Furthermore, it may be seen that if all of the No. 3 string ST3 that is the string SEL_ST that has been selected for the read operation, the strings ST<4, 5, 6, 7> that have been selected as the first strings, and the strings ST<4, 8, 1, 2> that have been selected as the second strings are combined, each of the eight strings ST<1:8> is included at least once. Accordingly, it may be seen that when each of the channel-initializing operation that is included in the read operation for the first logical page LSB and the channel-initializing operation that is included in the read operation for the second logical page MSB is performed once, at least one channel-initializing operation is performed on each of the eight strings ST<1:8>.

Furthermore, when a physical location of the string SEL_ST that has been selected as a read target is No. 6 (ST6), the control unit 202 may select, as first strings, the strings ST<7, 8, 1, 2> having physical locations of Nos. 7, 8, 1, and 2, respectively, among the seven unselected strings UNSEL_ST, ST<1, 2, 3, 4, 5, 7, 8>, along with the No. 6 string ST6 that is a string SEL_ST that has been selected for a read operation for the first logical page LSB. Accordingly, in the read operation for the first logical page LSB, the control unit 202 may perform a channel-initializing operation on the Nos. 6, 7, 8, 1, and 2 strings ST<6, 7, 8, 1, 2>. That is, in the read operation for the first logical page LSB, the control unit 202 may perform the channel-initializing operation on the five strings ST<6, 7, 8, 1, 2>, that is, half or more of the eight strings ST<1:8>. Furthermore, in the read operation for the first logical page LSB, the control unit 202 may perform the channel-initializing operation on only the four strings ST<7, 8, 1, 2>, that is, some of the seven unselected strings UNSEL_ST, ST<1, 2, 3, 4, 5, 7, 8>.

Furthermore, the control unit 202 may select, as second strings, the strings ST<7, 3, 4, 5> having physical locations of Nos. 7, 3, 4, and 5, respectively, among the seven unselected strings UNSEL_ST, ST<1, 2, 3, 4, 5, 7, 8>, along with the No. 6 string ST6 that is a string SEL_ST that has been selected for a read operation for the second logical page MSB. Accordingly, in the read operation for the second logical page MSB, the control unit 202 may perform a channel-initializing operation on the Nos. 6, 7, 3, 4, and 5 strings ST<6, 7, 3, 4, 5>. That is, in the read operation for the second logical page MSB, the control unit 202 may perform the channel-initializing operation on the five strings ST<6, 7, 3, 4, 5>, that is, half or more of the eight strings ST<1:8>. Furthermore, in the read operation for the second logical page MSB, the control unit 202 may perform the channel-initializing operation on only the four strings ST<7, 3, 4, 5>, that is, some of the seven unselected strings UNSEL_ST, ST<1, 2, 3, 4, 5, 7, 8>.

Furthermore, when the strings ST<7, 3, 4, 5> that have been selected as the second strings are compared with the strings ST<7, 8, 1, 2> that have been selected as the first strings, it may be seen that some strings ST7 overlap each other and some other strings ST<8, 1, 2> do not overlap the strings ST<3, 4, 5>. Furthermore, when the strings ST<7, 8, 1, 2> that have been selected as the first strings are compared with the strings ST<7, 3, 4, 5> that have been selected as the second strings, it may be seen that some strings ST7 overlap each other and some other strings ST<3, 4, 5> do not overlap the strings ST<8, 1, 2>. Furthermore, it may be seen that if all of the No. 6 string ST6 that is the string SEL_ST that has been selected for the read operation, the strings ST<7, 8, 1, 2> that have been selected as the first strings, and the strings ST<7, 3, 4, 5> that have been selected as the second strings are compared, each of the eight strings ST<1:8> is included at least once. Accordingly, it may be seen that when each of the channel-initializing operation that is included in the read operation for the first logical page LSB and the channel-initializing operation that is included in the read operation for the second logical page MSB is performed once, at least one channel-initializing operation is performed on each of the eight strings ST<1:8>.

As in the aforementioned embodiment, when a physical location of a string SEL_ST that has been selected as a read target is No. 3 (ST3), it may be seen that strings that have been selected as first strings are ST<4, 5, 6, 7>, strings that have been selected as second strings are ST<4, 8, 1, 2>, some strings that overlap each other are ST4, and strings that do not overlap each other are ST<5, 6, 7 or 8, 1, 2>. In contrast, when the physical location of the string SEL_ST that has been selected as the read target is No. 6 (ST6), it may be seen that strings that have been selected as first strings are ST<7, 8, 1, 2>, strings that have been selected as second strings are ST<7, 3, 4, 5>, some strings that overlap each other are ST7, and strings that do not overlap each other are ST<8, 1, 2 or 3, 4, 5>. That is, it may be seen that strings that overlap each other between the first string and the second string are changed into one of ST4 and ST7 depending on whether the physical location of the selected string SEL_ST is No. 3 (ST3) or No. 6 (ST6). Furthermore, it may be seen that strings that do not overlap each other between the first string and the second string are changed into one of ST<5, 6, 7 or 8, 1, 2> and ST<8, 1, 2 or 3, 4, 5> depending on whether the physical location of the selected string SEL_ST is No. 3 (ST3) or No. 6 (ST6).

In the aforementioned embodiment, in the state in which the first logical page LSB and the second logical page MSB correspond to the selected physical page SEL_PY_PG, the contents that have been described with respect to the case in which the physical location of the string SEL_ST that has been selected as the read target is the No. 3 (ST3) and the contents that have been described with respect to the case in which the physical location of the string SEL_ST that has been selected as the read target is the No. 6 (ST6) may also be identically applied to each of cases in which the physical locations of the selected strings SEL_ST are Nos. 1, 2, 4, 5, 7, and 8 (ST<1, 2, 4, 5, 7, 8>). Accordingly, for the detailed contents of the strings ST<1, 2, 4, 5, 7, 8>, reference may be made to FIG. 3B.

A detailed embodiment is described as follows with reference to FIGS. 4A and 4B.

First, in the description related to FIG. 4A, K is 16. Accordingly, in the following description, K is 16 and L is 9.

Referring to FIG. 4B, it may be seen that a change in the physical location of a string SEL_ST that has been selected as a read target, among the sixteen strings ST<1:16>, is divided as a row, and two logical pages LSB and MSB corresponding to a physical page SEL_PY_PG that has been selected as a read target are divided as a column.

First, when a physical location of the string SEL_ST that has been selected as the read target is No. 2 (ST2), the control unit 202 may select, as first strings, the strings ST<3, 4, 5, 6, 7, 8, 9, 10, 11> having physical locations of Nos. 3, 4, 5, 6, 7, 8, 9, 10, and 11, respectively, among the fifteen unselected strings UNSEL_ST, ST<1, 3, 4, 5, 6, 7, 8, 9, 10, 11, 12, 13, 14, 15, 16>, along with the No. 2 string ST2 that is a string SEL_ST that has been selected for a read operation for the first logical page LSB. Accordingly, in the read operation for the first logical page LSB, the control unit 202 may perform a channel-initializing operation on the Nos. 2 to 11 strings ST<2, 3, 4, 5, 6, 7, 8, 9, 10, 11>. That is, in the read operation for the first logical page LSB, the control unit 202 may perform the channel-initializing operation on the ten strings ST<2, 3, 4, 5, 6, 7, 8, 9, 10, 11>, that is, half or more of the sixteen strings ST<1:16>. Furthermore, in the read operation for the first logical page LSB, the control unit 202 may perform the channel-initializing operation on only the nine strings ST<3, 4, 5, 6, 7, 8, 9, 10, 11>, that is, some of the fifteen unselected strings UNSEL_ST, ST<1, 3, 4, 5, 6, 7, 8, 9, 10, 11, 12, 13, 14, 15, 16>.

Furthermore, the control unit 202 may select, as second strings, the strings ST<3, 4, 5, 12, 13, 14, 15, 16, 1> having physical locations of Nos. 3, 4, 5, 12, 13, 14, 15, 16, and 1, respectively, among the fifteen unselected strings UNSEL_ST, ST<1, 3, 4, 5, 6, 7, 8, 9, 10, 11, 12, 13, 14, 15, 16>, along with the No. 2 string ST2 that is a string SEL_ST that has been selected for a read operation for the second logical page MSB. Accordingly, in the read operation for the second logical page MSB, the control unit 202 may perform a channel-initializing operation on the Nos. 2, 3, 4, 5, 12, 13, 14, 15, 16, and 1 strings ST<2, 3, 4, 5, 12, 13, 14, 15, 16, 1>. That is, in the read operation for the second logical page MSB, the control unit 202 may perform the channel-initializing operation on the ten strings ST<2, 3, 4, 5, 12, 13, 14, 15, 16, 1>, that is, half or more of the sixteen strings ST<1:16>. Furthermore, in the read operation for the second logical page MSB, the control unit 202 may perform the channel-initializing operation on only the nine strings ST<3, 4, 5, 12, 13, 14, 15, 16, 1>, that is, some of the fifteen unselected strings UNSEL_ST, ST<1, 3, 4, 5, 6, 7, 8, 9, 10, 11, 12, 13, 14, 15, 16>.

Furthermore, when the strings ST<3, 4, 5, 12, 13, 14, 15, 16, 1> that have been selected as the second strings are compared with the strings ST<3, 4, 5, 6, 7, 8, 9, 10, 11> that have been selected as the first strings, it may be seen that some strings ST<3, 4, 5> overlap each other and some other strings ST<6, 7, 8, 9, 10, 11> do not overlap the strings ST<12, 13, 14, 15, 16, 1>. Furthermore, when the strings ST<3, 4, 5, 6, 7, 8, 9, 10, 11> that have been selected as the first strings are compared with the strings ST<3, 4, 5, 12, 13, 14, 15, 16, 1> that have been selected as the second strings, it may be seen that some strings ST<3, 4, 5> overlap each other and some other strings ST<12, 13, 14, 15, 16, 1> do not overlap the strings ST<6, 7, 8, 9, 10, 11>. Furthermore, it may be seen that if all of the No. 2 string ST2 that is the string SEL_ST that has been selected for the read operation, the strings ST<3, 4, 5, 6, 7, 8, 9, 10, 11> that have been selected as the first strings, and the strings ST<3, 4, 5, 12, 13, 14, 15, 16, 1> that have been selected as the second strings are combined, each of the sixteen strings ST<1:16> is included at least once. Accordingly, it may be seen that when each of the channel-initializing operation that is included in the read operation for the first logical page LSB and the channel-initializing operation that is included in the read operation for the second logical page MSB is performed once, at least one channel-initializing operation is performed on each of the sixteen strings ST<1:16>.

Furthermore, when a physical location of the string SEL_ST that has been selected as a read target is No. 10 (ST10), the control unit 202 may select, as first strings, the strings ST<11, 12, 13, 14, 15, 16, 1, 2, 3> having physical locations of Nos. 11, 12, 13, 14, 15, 16, 1, 2, and 3, respectively, among the fifteen unselected strings UNSEL_ST, ST<1, 2, 3, 4, 5, 6, 7, 8, 9, 11, 12, 13, 14, 15, 16>, along with the No. 10 string ST10 that is a string SEL_ST that has been selected for a read operation for the first logical page LSB. Accordingly, in the read operation for the first logical page LSB, the control unit 202 may perform a channel-initializing operation on the Nos. 10, 11, 12, 13, 14, 15, 16, 1, 2, and 3 strings ST<10, 11, 12, 13, 14, 15, 16, 1, 2, 3>. That is, in the read operation for the first logical page LSB, the control unit 202 may perform a channel-initializing operation on the ten strings ST<10, 11, 12, 13, 14, 15, 16, 1, 2, 3>, that is, half or more of the sixteen strings ST<1:16>. Furthermore, in the read operation for the first logical page LSB, the control unit 202 may perform the channel-initializing operation on only the nine strings ST<11, 12, 13, 14, 15, 16, 1, 2, 3>, that is, some of the fifteen unselected strings UNSEL_ST, ST<1, 2, 3, 4, 5, 6, 7, 8, 9, 11, 12, 13, 14, 15, 16>.

Furthermore, the control unit 202 may select, as second strings, the strings ST<11, 12, 13, 4, 5, 6, 7, 8, 9>having physical locations of Nos. 11, 12, 13, 4, 5, 6, 7, 8, and 9, respectively, among the fifteen unselected strings UNSEL_ST, ST<1, 2, 3, 4, 5, 6, 7, 8, 9, 11, 12, 13, 14, 15, 16>, along with the No. 10 string ST10 that is a string SEL_ST that has been selected for a read operation for the second logical page MSB. Accordingly, in the read operation for the second logical page MSB, the control unit 202 may perform a channel-initializing operation on the Nos. 10, 11, 12, 13, 4, 5, 6, 7, 8, and 9 strings ST<10, 11, 12, 13, 4, 5, 6, 7, 8, 9>. That is, in the read operation for the second logical page MSB, the control unit 202 may perform the channel-initializing operation on the ten strings ST<10, 11, 12, 13, 4, 5, 6, 7, 8, 9>, that is, half or more of the sixteen strings ST<1:16>. Furthermore, in the read operation for the second logical page MSB, the control unit 202 may perform the channel-initializing operation on only the nine strings ST<11, 12, 13, 4, 5, 6, 7, 8, 9>, that is, some of the fifteen unselected strings UNSEL_ST, ST<1, 2, 3, 4, 5, 6, 7, 8, 9, 11, 12, 13, 14, 15, 16>.

Furthermore, when the strings ST<11, 12, 13, 4, 5, 6, 7, 8, 9> that have been selected as the second strings are compared with the strings ST<11, 12, 13, 14, 15, 16, 1, 2, 3> that have been selected as the first strings, it may be seen that some strings ST<11, 12, 13> overlap each other and some other strings ST<14, 15, 16, 1, 2, 3> do not overlap the strings ST<4, 5, 6, 7, 8, 9>. Furthermore, when the strings ST<11, 12, 13, 14, 15, 16, 1, 2, 3> that have been selected as the first strings are compared with the strings ST<11, 12, 13, 4, 5, 6, 7, 8, 9> that have been selected as the second strings, it may be seen that some strings ST<11, 12, 13> overlap each other and some other strings ST<4, 5, 6, 7, 8, 9> do not overlap the strings ST<14, 15, 16, 1, 2, 3>. Furthermore, it may be seen that if all of the No. 10 string ST10 that is the string SEL_ST that has been selected for the read operation, the strings ST<11, 12, 13, 14, 15, 16, 1, 2, 3> that have been selected as the first strings, and the strings ST<11, 12, 13, 4, 5, 6, 7, 8, 9> that have been selected as the second strings are combined, each of the sixteen strings ST<1:16> is included at least once. Accordingly, it may be seen that when each of the channel-initializing operation that is included in the read operation for the first logical page LSB and the channel-initializing operation that is included in the read operation for the second logical page MSB is performed once, at least one channel-initializing operation is performed on each of the sixteen strings ST<1:16>.

As in the aforementioned embodiment, when the physical location of the string SEL_ST that has been selected as the read target is No. 2 (ST2), it may be seen that strings that have been selected as the first strings are ST<3, 4, 5, 6, 7, 8, 9, 10, 11>, strings that have been selected as the second strings are ST<3, 4, 5, 12, 13, 14, 15, 16, 1>, some strings that overlap each other are ST<3, 4, 5>, and strings that do not overlap each other are ST<6, 7, 8, 9, 10, 11 or 12, 13, 14, 15, 16, 1>. In contrast, when the physical location of the string SEL_ST that has been selected as the read target is No. 10 (ST10), it may be seen that strings that have been selected as the first strings are ST<11, 12, 13, 14, 15, 16, 1, 2, 3>, strings that have been selected as the second strings are ST<11, 12, 13, 4, 5, 6, 7, 8, 9>, some strings that overlap each other are ST<11, 12, 13>, and strings that do not overlap each other are ST<14, 15, 16, 1, 2, 3 or 4, 5, 6, 7, 8, 9>. That is, it may be seen that strings that overlap each other between the first string and the second string are changed into one of ST<3, 4, 5> and ST<11, 12, 13> depending on whether the physical location of the selected string SEL_ST is No. 2 (ST2) or the No. 10 (ST10). Furthermore, it may be seen that strings that do not overlap each other between the first string and the second string are changed into one of ST<6, 7, 8, 9, 10, 11 or 12, 13, 14, 15, 16, 1> and ST<14, 15, 16, 1, 2, 3 or 4, 5, 6, 7, 8, 9> depending on whether the physical location of the selected string SEL_ST is No. 2 (ST2) or the No. 10 (ST10).

In the aforementioned embodiment, in the state in which the first logical page LSB and the second logical page MSB correspond to the selected physical page SEL_PY_PG, the contents that have been described with respect to the case in which the physical location of the string SEL_ST that has been selected as the read target is the No. 2 (ST2) and the contents that have been described with respect to the case in which the physical location of the string SEL_ST that has been selected as the read target is the No. 10 (ST10) may also be identically applied to each of cases in which the physical locations of the selected strings SEL_ST are Nos. 1, 3, 4, 5, 6, 7, 8, 9, 11, 12, 13, 14, 15, and 16 (ST<1, 3, 4, 5, 6, 7, 8, 9, 11, 12, 13, 14, 15, 16>). Accordingly, for the detailed contents of the strings ST<1, 3, 4, 5, 6, 7, 8, 9, 11, 12, 13, 14, 15, 16>, reference may be made to FIG. 4B.

### In the Case of a Triple Level Cell

Referring to FIGS. 2C, 3C, and 4C, if the selected memory cells SEL_CELL configuring the selected physical page SEL_PY_PG are triple level cells in each of which 3-bit data is stored, that is, if a first logical page LSB, a second logical page CSB, and a third logical page MSB correspond to the selected physical page SEL_PY_PG, it may be seen that a method of controlling a channel-initializing operation in a read operation for the first logical page LSB, a method of controlling a channel-initializing operation in a read operation for the second logical page CSB, and a method of controlling a channel-initializing operation in a read operation for the third logical page MSB are different.

Specifically, if the first logical page LSB, the second logical page CSB, and the third logical page MSB correspond to the physical page SEL_PY_PG that has been selected by the selected word line SEL_WL, the multiple bit lines BL<1:m>, and the selected string SEL_ST, the control unit 202 may select L first strings of the (K−1) unselected strings UNSEL_ST except the selected string SEL_ST, among the K strings, L second strings some of which overlap the first strings and the others of which do not overlap the first strings, and L third strings some of which overlap each of the first and second strings and the others of which do not overlap each of the first and second strings. In this case, K may be a natural number equal to or greater than 2, and L may be a natural number less than K−1.

Furthermore, in the read operation for the first logical page LSB, the control unit 202 may perform a channel-initializing operation on one selected string SEL_ST, among the K strings, and the L first strings. That is, in the channel-initializing operation that is included in the read operation for the first logical page LSB, the control unit 202 may discharge the channel film of the one selected string SEL_ST, among the K strings, by connecting the channel film to a ground voltage stage, may discharge the channel films of the L first strings, among the (K−1) unselected strings UNSEL_ST, by connecting the channel films to the ground voltage stage, and may isolate, from the ground voltage stage, the channel films of the remaining unselected strings except the L first strings, among the (K−1) unselected strings UNSEL_ST.

Furthermore, in the read operation for the second logical page CSB, the control unit 202 may perform a channel-initializing operation on one selected string SEL_ST, among the K strings, and the L second strings. That is, in the channel-initializing operation that is included in the read operation for the second logical page CSB, the control unit 202 may discharge the channel film of the one selected string SEL_ST, among the K strings, by connecting the channel film to the ground voltage stage, may discharge the channel films of the L second strings, among the (K−1) unselected strings UNSEL_ST, by connecting the channel films to the to the ground voltage stage, and may isolate, from the ground voltage stage, the channel films of the remaining unselected strings except the L second strings, among the (K−1) unselected strings UNSEL_ST.

Furthermore, in the read operation for the third logical page MSB, the control unit 202 may perform a channel-initializing operation on one selected string SEL_ST, among the K strings, and the L third strings. That is, in the channel-initializing operation that is included in the read operation for the third logical page MSB, the control unit 202 may discharge the channel film of the one selected string SEL_ST, among the K strings, by connecting the channel film to the ground voltage stage, may discharge the channel films of the L third strings, among the (K−1) unselected strings UNSEL_ST, by connecting the channel films to the ground voltage stage, and may isolate, from the ground voltage stage, the channel films of the remaining unselected strings except the L third strings, among the (K−1) unselected strings UNSEL_ST.

In this case, it may be seen that each of the number of first strings, the number of second strings, and the number of third strings the channels of which are initialized through the channel-initializing operation is less than the number of (K−1) unselected strings UNSEL_ST because L is the natural number less than K−1.

Furthermore, the control unit 202 may set a number “L+1” as a number “K/2 or more”. That is, in one channel-initializing operation that is performed on one of the first to third strings, the control unit 202 may initialize a channel corresponding to half (K/2) or more of the K strings.

Furthermore, if the first logical page LSB, the second logical page CSB, and the third logical page MSB correspond to the selected physical page SEL_PY_PG, when the channel-initializing operation is performed on each of the first to third strings once, that is, when the three channel-initializing operations are performed on the first to third strings, the control unit 202 may properly select the first to third strings so that at least one channel-initializing operation is performed on each of the K strings. That is, the control unit 202 may properly select some strings that overlap each other between the first to third strings and the other strings that do not overlap each other between the first to third strings, so that at least one channel-initializing operation is performed on each of the K strings when the channel-initializing operation is performed on each of the first to third strings once.

Furthermore, the control unit 202 may adjust a number of the strings that overlap each other between the first to third strings based on the physical location of the selected string SEL_ST among the K strings. Furthermore, the control unit 202 may adjust the other strings that do not overlap each other between the first to third strings based on the physical location of the selected string SEL_ST among the K strings.

To wrap up, it may be seen that a difference between the method of controlling the channel-initializing operation in the read operation for the first logical page LSB and the method of controlling the channel-initializing operation in the read operation for the second logical page MSB, which have been disclosed with reference to FIGS. 2B, 3B, and 4B, may be expanded and applied to a difference between the method of controlling the channel-initializing operation in the read operation for the first logical page LSB and the method of controlling the channel-initializing operation in the read operation for the second logical page CSB, a difference between the method of controlling the channel-initializing operation in the read operation for the second logical page CSB and the method of controlling the channel-initializing operation in the read operation for the third logical page MSB, and a difference between the method of controlling the channel-initializing operation in the read operation for the first logical page LSB and the method of controlling the channel-initializing operation in the read operation for the third logical page MSB, which have been disclosed with reference to FIGS. 2C, 3C, and 4C.

A detailed embodiment is described as follows with reference to FIGS. 1, 2A, and 2C.

First, in the description related to FIGS. 1 and 2A, K is 6. Accordingly, in the following description, K is 6 and L is 3.

Referring to FIG. 2C, it may be seen that a change in the physical location of a string SEL_ST that has been selected as a read target, among the six strings ST<1:6>, is divided as a column, and the three logical pages LSB, CSB, and MSB corresponding to the physical page SEL_PY_PG that has been selected as a read target are divided as a row.

First, when a physical location of the string SEL_ST that has been selected as the read target is No. 1 (ST1), the control unit 202 may select, as first strings, the strings ST<2, 3, 4> having physical locations of Nos. 2, 3, and 4, respectively, among the five unselected strings UNSEL_ST, ST<2:6>, along with the No. 1 string ST1 that is a string SEL_ST that has been selected for a read operation for the first logical page LSB. Accordingly, in the read operation for the first logical page LSB, the control unit 202 may perform a channel-initializing operation on the Nos. 1 to 4 strings ST<1, 2, 3, 4>. That is, in the read operation for the first logical page LSB, the control unit 202 may perform the channel-initializing operation on the four strings ST<1, 2, 3, 4>, that is, half or more of the six strings ST<1:6>. Furthermore, in the read operation for the first logical page LSB, the control unit 202 may perform the channel-initializing operation on only the three strings ST<2, 3, 4>, that is, some of the five unselected strings UNSEL_ST, ST<2:6>.

Furthermore, the control unit 202 may select, as second strings, the strings ST<2, 4, 5> having physical locations of Nos. 2, 4, and 5, respectively, among the five unselected strings UNSEL_ST, ST<2:6>, along with the No. 1 string ST1 that is a string SEL_ST that has been selected for a read operation for the second logical page CSB. Accordingly, in the read operation for the second logical page CSB, the control unit 202 may perform a channel-initializing operation on the Nos. 1, 2, 4, and 5 strings ST<1, 2, 4, 5>. That is, in the read operation for the second logical page CSB, the control unit 202 may perform the channel-initializing operation on the four strings ST<1, 2, 4, 5>, that is, half or more of the six strings ST<1:6>. Furthermore, in the read operation for the second logical page CSB, the control unit 202 may perform the channel-initializing operation on the three strings ST<2, 4, 5>, that is, some of the five unselected strings UNSEL_ST, ST<2:6>.

Furthermore, the control unit 202 may select, as second strings, the strings ST<2, 5, 6> having physical locations of Nos. 2, 5, and 6, respectively, among the five unselected strings UNSEL_ST, ST<2:6>, along with the No. 1 string ST1 that is a string SEL_ST that has been selected for the read operation for the third logical page MSB. Accordingly, in the read operation for the third logical page MSB, the control unit 202 may perform a channel-initializing operation on the Nos. 1, 2, 5, and 6 strings ST<1, 2, 5, 6>. That is, in the read operation for the third logical page MSB, the control unit 202 may perform the channel-initializing operation on the four strings ST<1, 2, 5, 6>, that is, half or more of the six strings ST<1:6>. Furthermore, in the read operation for the third logical page MSB, the control unit 202 may perform the channel-initializing operation on only the three strings ST<2, 5, 6>, that is, some of the five unselected strings UNSEL_ST, ST<2:6>.

Furthermore, when the strings ST<2, 4, 5> that have been selected as the second strings are compared with the strings ST<2, 3, 4> that have been selected as the first strings, it may be seen that some strings ST<2, 4> overlap each other and some other strings ST3 and ST5 do not overlap each other. Furthermore, when the strings ST<2, 3, 4> that have been selected as the first strings are compared with the strings ST<2, 4, 5> that have been selected as the second strings, it may be seen that some strings ST<2, 4> overlap each other and some other strings ST5 and ST3 do not overlap each other. Furthermore, when the strings ST<2, 5, 6> that have been selected as the third string are compared with the strings ST<2, 3, 4> that have been selected as the first strings, it may be seen that some strings ST2 overlap each other and some other strings ST<3, 4> and ST<5, 6> do not overlap each other. Furthermore, when the strings ST<2, 3, 4> that have been selected as the first strings are compared with the strings ST<2, 5, 6> that have been selected as the third string, it may be seen that some strings ST2 overlap each other and some other strings ST<5, 6> and ST<3, 4> do not overlap each other. Furthermore, when the strings ST<2, 5, 6> that have been selected as the third string are compared with the strings ST<2, 4, 5> that have been selected as the second strings, it may be seen that some strings ST<2, 5> overlap each other and some other strings ST4 and ST6 do not overlap each other. Furthermore, when the strings ST<2, 4, 5> that have been selected as the second strings are compared with the strings ST<2, 5, 6> that have been selected as the third string, it may be seen that some strings ST<2, 5> overlap each other and some other strings ST6 and ST4 do not overlap each other.

Furthermore, it may be seen that if all of the No. 1 string ST1 that is the string SEL_ST that has been selected for the read operation, the strings ST<2, 3, 4> that have been selected as the first strings, and the strings ST<2, 4, 5> that have been selected as the second strings, and the strings ST<2, 5, 6> that have been selected as the third string are combined, each of the six strings ST<1:6> is included at least once. Accordingly, it may be seen that if each of the channel-initializing operation that is included in the read operation for the first logical page LSB, the channel-initializing operation that is included in the read operation for the second logical page CSB, and the channel-initializing operation that is included in the read operation for the third logical page MSB is performed once, at least one channel-initializing operation is performed on each of the six strings ST<1:6>.

Furthermore, when a physical location of the string SEL_ST that has been selected as a read target is No. 2 (ST2), the control unit 202 may select, as first strings, the strings ST<3, 4, 5> having physical locations of Nos. 3, 4, and 5, respectively, among the five unselected strings UNSEL_ST, ST<1, 3, 4, 5, 6>, along with the No. 2 string ST2 that is a string SEL_ST that has been selected for a read operation for the first logical page LSB. Accordingly, in the read operation for the first logical page LSB, the control unit 202 may perform a channel-initializing operation on the Nos. 2 to 5 strings ST<2, 3, 4, 5>. That is, in the read operation for the first logical page LSB, the control unit 202 may perform the channel-initializing operation on the four strings ST<2, 3, 4, 5>, that is, half or more of the six strings ST<1:6>. Furthermore, in the read operation for the first logical page LSB, the control unit 202 may perform the channel-initializing operation on only the three strings ST<3, 4, 5>, that is, some of the five unselected strings UNSEL_ST, ST<1, 3, 4, 5, 6>.

Furthermore, the control unit 202 may select, as second strings, the strings ST<3, 5, 6> having physical locations of Nos. 3, 5, and 6, respectively, among the five unselected strings UNSEL_ST, ST<1, 3, 4, 5, 6>, along with the No. 2 string ST2 that is a string SEL_ST that has been selected for a read operation for the second logical page CSB. Accordingly, in the read operation for the second logical page CSB, the control unit 202 may perform a channel-initializing operation on the Nos. 2, 3, 5, and 6 strings ST<2, 3, 5, 6>. That is, in the read operation for the second logical page CSB, the control unit 202 may perform the channel-initializing operation on the four strings ST<2, 3, 5, 6>, that is, half or more of the six strings ST<1:6>. Furthermore, in the read operation for the second logical page CSB, the control unit 202 may perform the channel-initializing operation on only the three strings ST<3, 5, 6>, that is, some of the five unselected strings UNSEL_ST, ST<1, 3, 4, 5, 6>.

Furthermore, the control unit 202 may select, as second strings, the strings ST<3, 6, 1> having physical locations of Nos. 3, 6, and 1, respectively, among the five unselected strings UNSEL_ST, ST<1, 3, 4, 5, 6>, along with the No. 2 string ST2 that is a string SEL_ST that has been selected for a read operation for the third logical page MSB. Accordingly, in the read operation for the third logical page MSB, the control unit 202 may perform a channel-initializing operation on the Nos. 2, 3, 6, and 1 strings ST<2, 3, 6, 1>. That is, in the read operation for the third logical page MSB, the control unit 202 may perform the channel-initializing operation on the four strings ST<2, 3, 6, 1>, that is, half or more of the six strings ST<1:6>. Furthermore, in the read operation for the third logical page MSB, the control unit 202 may perform the channel-initializing operation on only the three strings ST<3, 6, 1>, that is, some of the five unselected strings UNSEL_ST, ST<1, 3, 4, 5, 6>.

Furthermore, when the strings ST<3, 5, 6> that have been selected as the second strings are compared with the strings ST<3, 4, 5> that have been selected as the first strings, it may be seen that some strings ST<3, 5> overlap each other and some other strings ST4 and ST6 do not overlap each other. When the strings ST<3, 4, 5> that have been selected as the first strings are compared with the strings ST<3, 5, 6> that have been selected as the second strings, it may be seen that some strings ST<3, 5> overlap each other and some other strings ST6 and ST4 do not overlap each other. Furthermore, when the strings ST<3, 6, 1> that have been selected as the third string are compared with the strings ST<3, 4, 5> that have been selected as the first strings, it may be seen that some strings ST3 overlap each other and some other strings ST<4, 5> and ST<6, 1> do not overlap each other. Furthermore, when the strings ST<3, 4, 5> that have been selected as the first strings are compared with the strings ST<3, 6, 1> that have been selected as the third string, it may be seen that some strings ST3 overlap each other and some other strings ST<6, 1> and ST<4, 5> do not overlap each other. Furthermore, when the strings ST<3, 6, 1> that have been selected as the third string are compared with the strings ST<3, 5, 6> that have been selected as the second strings, it may be seen that some strings ST<3, 6> overlap each other and some other strings ST5 and ST1 do not overlap each other. Furthermore, when the strings ST<3, 5, 6> that have been selected as the second strings are compared with the strings ST<3, 6, 1> that have been selected as the third string, it may be seen that some strings ST<3, 6> overlap each other and some other strings ST1 and ST5 do not overlap each other.

Furthermore, it may be seen that if all of the No. 2 string ST2 that is the string SEL_ST that has been selected for the read operation, the strings ST<3, 4, 5> that have been selected as the first strings, the strings ST<3, 5, 6> that have been selected as the second strings, and the strings ST<3, 6, 1> that have been selected as the third string are combined, each of the six strings ST<1:6> is included at least once. Accordingly, it may be seen that if each of the channel-initializing operation that is included in the read operation for the first logical page LSB, the channel-initializing operation that is included in the read operation for the second logical page CSB, and the channel-initializing operation that is included in the read operation for the third logical page MSB is performed once, at least one channel-initializing operation is performed on each of the six strings ST<1:6>.

As in the aforementioned embodiment, when a physical location of a string SEL_ST that has been selected as a read target is No. 1 (ST1), it may be seen that strings that have been selected as first strings are ST<2, 3, 4>, strings that have been selected as second strings are ST<2, 4, 5>, strings that have been selected as third strings are ST<2, 5, 6>, some strings that overlap each other between the first string and the second string are ST<2, 4>, strings that do not overlap each other between the first string and the second string are ST<3 or 5>, some strings that overlap each other between the first string and the third string are ST2, strings that do not overlap each other between the first string and the third string are ST<3, 4 or 5, 6>, some strings that overlap each other between the second string and the third string are ST<2, 5>, and strings that do not overlap the second string and the third string are ST<4 or 6>.

In contrast, when the physical location of the string SEL_ST that has been selected as the read target is No. 2 (ST2), it may be seen that strings that have been selected as first strings are ST<3, 4, 5>, strings that have been selected as second strings are ST<3, 5, 6>, strings that have been selected as third strings are ST<3, 6, 1>, some strings that overlap each other between the first string and the second string are ST<3, 5>, strings that do not overlap each other between the first string and the second string are ST<4 or 6>, some strings that overlap each other between the first string and the third string are ST3, strings that do not overlap each other between the first string and the third string are ST<4, 5 or 6, 1>, some strings that overlap each other between the second string and the third string are ST<3, 6>, and strings that do not overlap each other between the second string and the third string are ST<5 or 1>.

That is, it may be seen that whether strings that overlap each other between the first to third strings will be selected among ST<2, 4, 5> or ST<3, 5, 6> is determined depending on whether the physical location of the selected string SEL_ST is the No. 1 (ST1) or the No. 2 (ST2). Furthermore, it may be seen that whether a string that does not overlap each other between the first string and the second string will be selected among ST<3, 4, 5, 6> or ST<4, 5, 6, 1> is determined depending on whether the physical location of the selected string SEL_ST is the No. 1 (ST1) or the No. 2 (ST2).

In the aforementioned embodiment, in the state in which the first logical page LSB, the second logical page CSB, and the third logical page MSB correspond to the selected physical page SEL_PY_PG, the contents that have been described with respect to the case in which the physical location of the string SEL_ST that has been selected as the read target is the No. 1 (ST1) and the contents that have been described with respect to the case in which the physical location of the string SEL_ST that has been selected as the read target is the No. 2 (ST2) may also be identically applied to each of cases in which the physical locations of the selected strings SEL_ST are Nos. 3 to 6 (ST<3, 4, 5, 6>). Accordingly, for the detailed contents of the strings ST<3, 4, 5, 6>, reference may be made to FIG. 2C.

A detailed embodiment is described as follows with reference to FIGS. 3A and 3C.

First, in the description related to FIG. 3A, K is 8. Accordingly, in the following description, K is 8 and L is 3.

Referring to FIG. 3C, it may be seen that a change in the physical location of a string SEL_ST that has been selected as a read target, among the eight strings ST<1:8>, is divided as a column, and three logical pages LSB, CSB, and MSB corresponding to a physical page SEL_PY_PG that has been selected as a read target are divided as rows.

First, when a physical location of the string SEL_ST that has been selected as the read target is No. 3 (ST3), the control unit 202 may select, as first strings, the strings ST<4, 5, 6> having physical locations of Nos. 4, 5, and 6, respectively, among the seven unselected strings UNSEL_ST, ST<1, 2, 4, 5, 6, 7, 8>, along with the No. 3 string ST3 that is a string SEL_ST that has been selected for a read operation for the first logical page LSB. Accordingly, in the read operation for the first logical page LSB, the control unit 202 may perform a channel-initializing operation on the Nos. 3 to 6 strings ST<3, 4, 5, 6>. That is, in the read operation for the first logical page LSB, the control unit 202 may perform the channel-initializing operation on the four strings ST<3, 4, 5, 6>, that is, half of the eight strings ST<1:8>. Furthermore, in the read operation for the first logical page LSB, the control unit 202 may perform the channel-initializing operation on only the three strings ST<4, 5, 6>, that is, some of the seven unselected strings UNSEL_ST, ST<1, 2, 4, 5, 6, 7, 8>.

Furthermore, the control unit 202 may select, as second strings the strings ST<4, 7, 8> having physical locations of Nos. 4, 7, and 8, respectively, among the seven unselected strings UNSEL_ST, ST<1, 2, 4, 5, 6, 7, 8>, along with the No. 3 string ST3 that is a string SEL_ST that has been selected for a read operation for the second logical page CSB. Accordingly, in the read operation for the second logical page CSB, the control unit 202 may perform a channel-initializing operation on the Nos. 3, 4, 7, and 8 strings ST<3, 4, 7, 8>. That is, in the read operation for the second logical page CSB, the control unit 202 may perform the channel-initializing operation the four strings ST<3, 4, 7, 8>, that is, half of the eight strings ST<1:8>. Furthermore, in the read operation for the second logical page CSB, the control unit 202 may perform the channel-initializing operation on only the three strings ST<4, 7, 8>, that is, some of the seven unselected strings UNSEL_ST, ST<1, 2, 4, 5, 6, 7, 8>.

Furthermore, the control unit 202 may select, as second strings, the strings ST<4, 1, 2> having physical locations of Nos. 4, 1, and 2, respectively, among the seven unselected strings UNSEL_ST, ST<1, 2, 4, 5, 6, 7, 8>, along with the No. 3 string ST3 that is a string SEL_ST that has been selected for a read operation for the third logical page MSB. Accordingly, in the read operation for the third logical page MSB, the control unit 202 may perform a channel-initializing operation on the Nos. 3, 4, 1, and 2 strings ST<3, 4, 1, 2>. That is, in the read operation for the third logical page MSB, the control unit 202 may perform the channel-initializing operation on the four strings ST<3, 4, 1, 2>, that is, half of the eight strings ST<1:8>. Furthermore, in the read operation for the third logical page MSB, the control unit 202 may perform the channel-initializing operation on only the three strings ST<4, 1, 2>, that is, some of the seven unselected strings UNSEL_ST, ST<1, 2, 4, 5, 6, 7, 8>.

Furthermore, when the strings ST<4, 7, 8> that have been selected as the second strings are compared with the strings ST<4, 5, 6> that have been selected as the first strings, it may be seen that some strings ST4 overlap each other and some other strings ST<5, 6> and ST<7, 8> do not overlap each other. Furthermore, when the strings ST<4, 5, 6> that have been selected as the first strings are compared with the strings ST<4, 7, 8> that have been selected as the second strings, it may be seen that some strings ST4 overlap each other and some other strings ST<7, 8> and ST<5, 6> do not overlap each other. Furthermore, when the strings ST<4, 1, 2> that have been selected as the third string are compared with the strings ST<4, 5, 6> that have been selected as the first strings, it may be seen that some strings ST4 overlap each other and some other strings ST<5, 6> and ST<1, 2> do not overlap each other. Furthermore, when the strings ST<4, 5, 6> that have been selected as the first strings are compared with the strings ST<4, 1, 2> that have been selected as the third string, it may be seen that some strings ST4 overlap each other and some other strings ST<1, 2> and ST<5, 6> do not overlap each other. Furthermore, when the strings ST<4, 1, 2> that have been selected as the third string are compared with the strings ST<4, 7, 8> that have been selected as the second strings, it may be seen that some strings ST4 overlap each other and some other strings ST<7, 8> and ST<1, 2> do not overlap each other. Furthermore, when the strings ST<4, 7, 8> that have been selected as the second strings are compared with the strings ST<4, 1, 2> that have been selected as the third string, it may be seen that some strings ST4 overlap each other and some other strings ST<1, 2> and ST<7, 8> do not overlap each other.

Furthermore, it may be seen that if all of the No. 3 string ST3 that is the string SEL_ST that has been selected for the read operation, the strings ST<4, 5, 6> that have been selected as the first strings, the strings ST<4, 7, 8> that have been selected as the second strings, and the strings ST<4, 1, 2> that have been selected as the third string are combined, each of the eight strings ST<1:8> is included at least once. Accordingly, it may be seen that if each of the channel-initializing operation that is included in the read operation for the first logical page LSB, the channel-initializing operation that is included in the read operation for the second logical page CSB, and the channel-initializing operation that is included in the read operation for the third logical page MSB is performed once, at least one channel-initializing operation is performed on each of the eight strings ST<1:8>.

Furthermore, when a physical location of the string SEL_ST that has been selected as a read target is No. 6 (ST6), the control unit 202 may select, as first strings, the strings ST<7, 8, 1> having physical locations of Nos. 7, 8, and 1, respectively, among the seven unselected strings UNSEL_ST, ST<1, 2, 3, 4, 5, 7, 8>, along with the No. 6 string ST6 that is a string SEL_ST that has been selected for a read operation for the first logical page LSB. Accordingly, in the read operation for the first logical page LSB, the control unit 202 may perform a channel-initializing operation on the Nos. 6, 7, 8, and 1 strings ST<6, 7, 8, 1>. That is, in the read operation for the first logical page LSB, the control unit 202 may perform the channel-initializing operation on the four strings ST<6, 7, 8, 1>, that is, half of the eight strings ST<1:8>. Furthermore, in the read operation for the first logical page LSB, the control unit 202 may perform the channel-initializing operation on only the three strings ST<7, 8, 1>, that is, some of the seven unselected strings UNSEL_ST, ST<1, 2, 3, 4, 5, 7, 8>.

Furthermore, the control unit 202 may select, as second strings, the strings ST<7, 2, 3> having physical locations of Nos. 7, 2, and 3, respectively, among the seven unselected strings UNSEL_ST, ST<1, 2, 3, 4, 5, 7, 8>, along with the No. 6 string ST6 that is a string SEL_ST that has been selected for a read operation for the second logical page CSB. Accordingly, in the read operation for the second logical page CSB, the control unit 202 may perform a channel-initializing operation on the Nos. 6, 7, 2, and 3 strings ST<6, 7, 2, 3>. That is, in the read operation for the second logical page CSB, the control unit 202 may perform the channel-initializing operation on the four strings ST<6, 7, 2, 3>, that is, half of the eight strings ST<1:8>. Furthermore, in the read operation for the second logical page CSB, the control unit 202 may perform the channel-initializing operation on only the three strings ST<7, 2, 3>, that is, some of the seven unselected strings UNSEL_ST, ST<1, 2, 3, 4, 5, 7, 8>.

Furthermore, the control unit 202 may select, as third strings, the strings ST<7, 4, 5> having physical locations of Nos. 7, 4, and 5, respectively, among the seven unselected strings UNSEL_ST, ST<1, 2, 3, 4, 5, 7, 8>, along with the No. 6 string ST6 that is a string SEL_ST that has been selected for a read operation for the third logical page MSB. Accordingly, in the read operation for the third logical page MSB, the control unit 202 may perform a channel-initializing operation on the Nos. 6, 7, 4, and 5 strings ST<6, 7, 4, 5>. That is, in the read operation for the third logical page MSB, the control unit 202 may perform the channel-initializing operation on the four strings ST<6, 7, 4, 5>, that is, half of the eight strings ST<1:8>. Furthermore, in the read operation for the third logical page MSB, the control unit 202 may perform the channel-initializing operation on only the three strings ST<7, 4, 5>, that is, some of the seven unselected strings UNSEL_ST, ST<1, 2, 3, 4, 5, 7, 8>.

Furthermore, when the strings ST<7, 2, 3> that have been selected as the second strings are compared with the strings ST<7, 8, 1> that have been selected as the first strings, it may be seen that some strings ST7 overlap each other and some other strings ST<8, 1> and ST<2, 3> do not overlap each other. Furthermore, when the strings ST<7, 8, 1> that have been selected as the first strings are compared with the strings ST<7, 2, 3> that have been selected as the second strings, it may be seen that some strings ST7 overlap each other and some other strings ST<2, 3> and ST<8, 1> do not overlap each other. Furthermore, when the strings ST<7, 4, 5> that have been selected as the third string are compared with the strings ST<7, 8, 1> that have been selected as the first strings, it may be seen that some strings ST7 overlap each other and some other strings ST<8, 1> and ST<4, 5> do not overlap each other. Furthermore, when the strings ST<7, 8, 1> that have been selected as the first strings are compared with the strings ST<7, 4, 5> that have been selected as the third string, it may be seen that some strings ST7 overlap each other and some other strings ST<4, 5> and ST<8, 1> do not overlap each other. Furthermore, when the strings ST<7, 4, 5> that have been selected as the third string are compared with the strings ST<7, 2, 3> that have been selected as the second strings, it may be seen that some strings ST7 overlap each other and some other strings ST<2, 3> and ST<4, 5> do not overlap each other. Furthermore, when the strings ST<7, 2, 3> that have been selected as the second strings are compared with the strings ST<7, 4, 5> that have been selected as the third string, it may be seen that some strings ST7 overlap each other and some other strings ST<4, 5> and ST<2, 3> do not overlap each other.

Furthermore, it may be seen that if all of the No. 6 string ST6 that is the string SEL_ST that has been selected for the read operation, the strings ST<7, 8, 1> that have been selected as the first strings, the strings ST<7, 2, 3> that have been selected as the second strings, and the strings ST<7, 4, 5> that have been selected as the third string are combined, each of the eight strings ST<1:8> is included at least once. Accordingly, it may be seen that if each of the channel-initializing operation that is included in the read operation for the first logical page LSB, the channel-initializing operation that is included in the read operation for the second logical page CSB, and the channel-initializing operation that is included in the read operation for the third logical page MSB is performed once, at least one channel-initializing operation is performed on each of the eight strings ST<1:8>.

As in the aforementioned embodiment, when a physical location of a string SEL_ST that has been selected as a read target is No. 3 (ST3), it may be seen that strings that have been selected as first strings are ST<4, 5, 6>, strings that have been selected as second strings are ST<4, 7, 8>, strings that have been selected as third strings are ST<4, 1, 2>, some strings that overlap each other between the first string and the second string are ST4, strings that do not overlap each other between the first string and the second string are ST<5, 6 or 7, 8>, some strings that overlap each other between the first string and the third string are ST4, strings that do not overlap each other between the first string and the third string are ST<5, 6 or 1, 2>, some strings that overlap each other between the second string and the third string are ST4, and strings that do not overlap each other between the second string and the third string are ST<7, 8 or 1, 2>.

In contrast, when the physical location of the string SEL_ST that has been selected as the read target is No. 6 (ST6), it may be seen that strings that have been selected as first strings are ST<7, 8, 1>, strings that have been selected as second strings are ST<7, 2, 3>, strings that have been selected as third strings are ST<7, 4, 5>, some strings that overlap each other between the first string and the second string are ST7, strings that do not overlap each other between the first string and the second string are ST<8, 1 or 2, 3>, some strings that overlap each other between the first string and the third string are ST7, strings that do not overlap each other between the first string and the third string are ST<8, 1 or 4, 5>, some strings that overlap each other between the second string and the third string are ST7, and strings that do not overlap each other between the second string and the third string are ST<2, 3 or 4, 5>.

That is, it may be seen that strings that overlap each other between the first to third strings are changed into one of ST4 and ST7 depending on whether the physical location of the selected string SEL_ST is the No. 3 (ST3) or the No. 6 (ST6). Furthermore, it may be seen that whether strings that do not overlap each other between the first to third strings will be selected among ST<5, 6, 7, 8, 1, 2> or ST<8, 1, 2, 3, 4, 5> is determined depending on whether the physical location of the selected string SEL_ST is the No. 3 (ST3) or the No. 6 (ST6).

In the aforementioned embodiment, in the state in which the first logical page LSB, the second logical page CSB, and the third logical page MSB correspond to the selected physical page SEL_PY_PG, the contents that have been described with respect to the case in which the physical location of the string SEL_ST that has been selected as the read target is No. 3 (ST3) and the contents that have been described with respect to the case in which the physical location of the string SEL_ST that has been selected as the read target is No. 6 (ST6) may also be identically applied to each of cases in which the physical locations of the selected strings SEL_ST are Nos. 1, 2, 4, 5, 7, and 8 (ST<1, 2, 4, 5, 7, 8>). Accordingly, for the detailed contents of the strings ST<1, 2, 4, 5, 7, 8>, reference may be made to FIG. 3C.

A detailed embodiment is described as follows with reference to FIGS. 4A and 4C.

First, in the description related to FIG. 4A, K is 16. Accordingly, in the following description, K is 16 and L is 7.

Referring to FIG. 4C, it may be seen that a change in the physical location of a string SEL_ST that has been selected as a read target, among the sixteen strings ST<1:16>, is divided as a row, and three logical pages LSB, CSB, and MSB corresponding to a physical page SEL_PY_PG that has been selected as a read target are divided as columns.

First, when a physical location of the string SEL_ST that has been selected as the read target is No. 2 (ST2), the control unit 202 may select, as first strings, the strings ST<3, 4, 5, 6, 7, 8, 9> having physical locations of Nos. 3, 4, 5, 6, 7, 8, and 9, respectively, among the fifteen unselected strings UNSEL_ST, ST<1, 3, 4, 5, 6, 7, 8, 9, 10, 11, 12, 13, 14, 15, 16>, along with the No. 2 string ST2 that is a string SEL_ST that has been selected for a read operation for the first logical page LSB. Accordingly, in the read operation for the first logical page LSB, the control unit 202 may perform a channel-initializing operation on the Nos. 2 to 9 strings ST<2, 3, 4, 5, 6, 7, 8, 9>. That is, in the read operation for the first logical page LSB, the control unit 202 may perform the channel-initializing operation on the eight strings ST<2, 3, 4, 5, 6, 7, 8, 9>, that is, half of the sixteen strings ST<1:16>. Furthermore, in the read operation for the first logical page LSB, the control unit 202 may perform the channel-initializing operation on only the seven strings ST<3, 4, 5, 6, 7, 8, 9>, that is, some of the fifteen unselected strings UNSEL_ST, ST<1, 3, 4, 5, 6, 7, 8, 9, 10, 11, 12, 13, 14, 15, 16>.

Furthermore, the control unit 202 may select, as second strings the strings ST<3, 4, 5, 10, 11, 12, 13> having physical locations of Nos. 3, 4, 5, 10, 11, 12, and 13, respectively, among the fifteen unselected strings UNSEL_ST, ST<1, 3, 4, 5, 6, 7, 8, 9, 10, 11, 12, 13, 14, 15, 16>, along with the No. 2 string ST2 that is a string SEL_ST that has been selected for a read operation for the second logical page CSB. Accordingly, in the read operation for the second logical page CSB, the control unit 202 may perform a channel-initializing operation on the Nos. 2, 3, 4, 5, 10, 11, 12, and 13 strings ST<2, 3, 4, 5, 10, 11, 12, 13>. That is, in the read operation for the second logical page CSB, the control unit 202 may perform the channel-initializing operation on the eight strings ST<2, 3, 4, 5, 10, 11, 12, 13>, that is, half of the sixteen strings ST<1:16>. Furthermore, in the read operation for the second logical page CSB, the control unit 202 may perform the channel-initializing operation on only the seven strings ST<3, 4, 5, 10, 11, 12, 13>, that is, some of the fifteen unselected strings UNSEL_ST, ST<1, 3, 4, 5, 6, 7, 8, 9, 10, 11, 12, 13, 14, 15, 16>.

Furthermore, the control unit 202 may select, as second strings, the strings ST<3, 4, 5, 14, 15, 16, 1> having physical locations of Nos. 3, 4, 5, 14, 15, 16, and 1, respectively, among the fifteen unselected strings UNSEL_ST, ST<1, 3, 4, 5, 6, 7, 8, 9, 10, 11, 12, 13, 14, 15, 16>, along with the No. 2 string ST2 that is a string SEL_ST that has been selected for a read operation for the third logical page MSB. Accordingly, in the read operation for the third logical page MSB, the control unit 202 may perform a channel-initializing operation on the Nos. 2, 3, 4, 5, 4, 15, 16, and 1 strings ST<2, 3, 4, 5, 14, 15, 16, 1>. That is, in the read operation for the third logical page MSB, the control unit 202 may perform the channel-initializing operation on the eight strings ST<2, 3, 4, 5, 14, 15, 16, 1>, that is, half of the sixteen strings ST<1:16>. Furthermore, in the read operation for the third logical page MSB, the control unit 202 may perform the channel-initializing operation on only the seven strings ST<3, 4, 5, 14, 15, 16, 1>, that is, some of the fifteen unselected strings UNSEL_ST, ST<1, 3, 4, 5, 6, 7, 8, 9, 10, 11, 12, 13, 14, 15, 16>.

Furthermore, when the strings ST<3, 4, 5, 10, 11, 12, 13> that have been selected as the second strings are compared with the strings ST<3, 4, 5, 6, 7, 8, 9> that have been selected as the first strings, it may be seen that some strings ST<3, 4, 5> overlap each other and some other strings ST<6, 7, 8, 9> and ST<10, 11, 12, 13> do not overlap each other. Furthermore, when the strings ST<3, 4, 5, 6, 7, 8, 9> that have been selected as the first strings are compared with the strings ST<3, 4, 5, 10, 11, 12, 13> that have been selected as the second strings, it may be seen that some strings ST<3, 4, 5> overlap each other and some other strings ST<10, 11, 12, 13> and ST<6, 7, 8, 9> do not overlap each other. Furthermore, when the strings ST<3, 4, 5, 14, 15, 16, 1> that have been selected as the third string are compared with the strings ST<3, 4, 5, 6, 7, 8, 9> that have been selected as the first strings, it may be seen that some strings ST<3, 4, 5> overlap each other and some other strings ST<6, 7, 8, 9> and ST<14, 15, 16, 1> do not overlap each other. Furthermore, when the strings ST<3, 4, 5, 6, 7, 8, 9> that have been selected as the first strings are compared with the strings ST<3, 4, 5, 14, 15, 16, 1> that have been selected as the third string, it may be seen that some strings ST<3, 4, 5> overlap each other and some other strings ST<14, 15, 16, 1> and ST<6, 7, 8, 9> do not overlap each other. Furthermore, when the strings ST<3, 4, 5, 14, 15, 16, 1> that have been selected as the third string are compared with the strings ST<3, 4, 5, 10, 11, 12, 13> that have been selected as the second strings, it may be seen that some strings ST<3, 4, 5>overlap each other and some other strings ST<10, 11, 12, 13> and ST<14, 15, 16, 1> do not overlap each other. Furthermore, when the strings ST<3, 4, 5, 10, 11, 12, 13> that have been selected as the second strings are compared with the strings ST<3, 4, 5, 14, 15, 16, 1> that have been selected as the third string, it may be seen that some strings ST<3, 4, 5> overlap each other and some other strings ST<14, 15, 16, 1> and ST<10, 11, 12, 13> do not overlap each other.

Furthermore, it may be seen that if all of the No. 2 string ST2 that is the string SEL_ST that has been selected for the read operation, the strings ST<3, 4, 5, 6, 7, 8, 9> that have been selected as the first strings, the strings ST<3, 4, 5, 10, 11, 12, 13> that have been selected as the second strings, and the strings ST<3, 4, 5, 14, 15, 16, 1> that have been selected as the third string are combined, each of the sixteen strings ST<1:16> is included at least once. Accordingly, it may be seen that if each of the channel-initializing operation that is included in the read operation for the first logical page LSB, the channel-initializing operation that is included in the read operation for the second logical page CSB, and the channel-initializing operation that is included in the read operation for the third logical page MSB is performed once, at least one channel-initializing operation is performed on each of the sixteen strings ST<1:16>.

Furthermore, when a physical location of the string SEL_ST that has been selected as a read target is No. 10 (ST10), the control unit 202 may select, as first strings, the strings ST<11, 12, 13, 14, 15, 16, 1> having physical locations of Nos. 11, 12, 13, 14, 15, 16, and 1, respectively, among the fifteen unselected strings UNSEL_ST, ST<1, 2, 3, 4, 5, 6, 7, 8, 9, 11, 12, 13, 14, 15, 16>, along with the No. 10 string ST10 that is a string SEL_ST that has been selected for a read operation for the first logical page LSB. Accordingly, in the read operation for the first logical page LSB, the control unit 202 may perform a channel-initializing operation on the Nos. 10, 11, 12, 13, 14, 15, 16, and 1 strings ST<10, 11, 12, 13, 14, 15, 16, 1>. That is, in the read operation for the first logical page LSB, the control unit 202 may perform the channel-initializing operation the eight strings ST<10, 11, 12, 13, 14, 15, 16, 1>, that is, half of the sixteen strings ST<1:16>. Furthermore, in the read operation for the first logical page LSB, the control unit 202 may perform the channel-initializing operation on only the seven strings ST<11, 12, 13, 14, 15, 16, 1>, that is, some of the fifteen unselected strings UNSEL_ST, ST<1, 2, 3, 4, 5, 6, 7, 8, 9, 11, 12, 13, 14, 15, 16>.

Furthermore, the control unit 202 may select, as second strings, the strings ST<11, 12, 13, 2, 3, 4, 5> having physical locations of Nos. 11, 12, 13, 2, 3, 4, and 5, respectively, among the fifteen unselected strings UNSEL_ST, ST<1, 2, 3, 4, 5, 6, 7, 8, 9, 11, 12, 13, 14, 15, 16>, along with the No. 10 string ST10 that is a string SEL_ST that has been selected for a read operation for the second logical page CSB. Accordingly, in the read operation for the second logical page CSB, the control unit 202 may perform a channel-initializing operation on the Nos. 10, 11, 12, 13, 2, 3, 4, and 5 strings ST<10, 11, 12, 13, 2, 3, 4, 5>. That is, in the read operation for the second logical page CSB, the control unit 202 may perform the channel-initializing operation on the eight strings ST<10, 11, 12, 13, 2, 3, 4, 5>, that is, half of the sixteen strings ST<1:16>. Furthermore, in the read operation for the second logical page CSB, the control unit 202 may perform the channel-initializing operation on only the seven strings ST<11, 12, 13, 2, 3, 4, 5>, that is, some of the fifteen unselected strings UNSEL_ST, ST<1, 2, 3, 4, 5, 6, 7, 8, 9, 11, 12, 13, 14, 15, 16>.

Furthermore, the control unit 202 may select, as third strings, the strings ST<11, 12, 13, 6, 7, 8, 9> having physical locations of Nos. 11, 12, 13, 6, 7, 8, and 9, respectively, among the fifteen unselected strings UNSEL_ST, ST<1, 2, 3, 4, 5, 6, 7, 8, 9, 11, 12, 13, 14, 15, 16>, along with the No. 10 string ST10 that is a string SEL_ST that has been selected for a read operation for the third logical page MSB. Accordingly, in the read operation for the third logical page MSB, the control unit 202 may perform a channel-initializing operation on the Nos. 10, 11, 12, 13, 6, 7, 8, and 9 strings ST<10, 11, 12, 13, 6, 7, 8, 9>. That is, in the read operation for the third logical page MSB, the control unit 202 may perform the channel-initializing operation on the ten strings ST<10, 11, 12, 13, 4, 5, 6, 7, 8, 9>, that is, half or more of the sixteen strings ST<1:16>. Furthermore, in the read operation for the third logical page MSB, the control unit 202 may perform the channel-initializing operation on only the seven strings ST<11, 12, 13, 6, 7, 8, 9>, that is, some of the fifteen unselected strings UNSEL_ST, ST<1, 2, 3, 4, 5, 6, 7, 8, 9, 11, 12, 13, 14, 15, 16>.

Furthermore, when the strings ST<11, 12, 13, 2, 3, 4, 5> that have been selected as the second strings are compared with the strings ST<11, 12, 13, 14, 15, 16, 1> that have been selected as the first strings, it may be seen that some strings ST<11, 12, 13> overlap each other and some other strings ST<14, 15, 16, 1> and ST<2, 3, 4, 5> do not overlap each other. Furthermore, when the strings ST<11, 12, 13, 14, 15, 16, 1> that have been selected as the first strings are compared with the strings ST<11, 12, 13, 2, 3, 4, 5> that have been selected as the second strings, it may be seen that some strings ST<11, 12, 13> overlap each other and some other strings ST<2, 3, 4, 5> and ST<14, 15, 16, 1> do not overlap each other. Furthermore, when the strings ST<11, 12, 13, 6, 7, 8, 9> that have been selected as the third string are compared with the strings ST<11, 12, 13, 14, 15, 16, 1> that have been selected as the first strings, it may be seen that some strings ST<11, 12, 13> overlap each other and some other strings ST<14, 15, 16, 1> and ST<6, 7, 8, 9> do not overlap each other. Furthermore, when the strings ST<11, 12, 13, 14, 15, 16, 1> that have been selected as the first strings are compared with the strings ST<11, 12, 13, 6, 7, 8, 9> that have been selected as the third string, it may be seen that some strings ST<11, 12, 13> overlap each other and some other strings ST<6, 7, 8, 9> and ST<14, 15, 16, 1> do not overlap each other. Furthermore, when the strings ST<11, 12, 13, 6, 7, 8, 9> that have been selected as the third string are compared with the strings ST<11, 12, 13, 2, 3, 4, 5> that have been selected as the second strings, it may be seen that some strings ST<11, 12, 13> overlap each other and some other strings ST<2, 3, 4, 5> and ST<6, 7, 8, 9> do not overlap each other. Furthermore, when the strings ST<11, 12, 13, 14, 2, 3, 4, 5> that have been selected as the second strings are compared with the strings ST<11, 12, 13, 6, 7, 8, 9> that have been selected as the third string, it may be seen that some strings ST<11, 12, 13> overlap each other and some other strings ST<6, 7, 8, 9> and ST<2, 3, 4, 5> do not overlap each other.

Furthermore, it may be seen that if all of the No. 10 string ST10 that is the string SEL_ST that has been selected for the read operation, the strings ST<11, 12, 13, 14, 15, 16, 1> that have been selected as the first strings, the strings ST<11, 12, 13, 2, 3, 4, 5> that have been selected as the second string, and the strings ST<11, 12, 13, 6, 7, 8, 9> that have been selected as the third string are combined, each of the sixteen strings ST<1:16> is included at least once. Accordingly, it may be seen that if each of the channel-initializing operation that is included in the read operation for the first logical page LSB, the channel-initializing operation that is included in the read operation for the second logical page CSB, and the channel-initializing operation that is included in the read operation for the third logical page MSB is performed once, at least one channel-initializing operation is performed on each of the sixteen strings ST<1:16>.

As in the aforementioned embodiment, when a physical location of a string SEL_ST that has been selected as a read target is No. 2 (ST2), it may be seen that strings that have been selected as first strings are ST<3, 4, 5, 6, 7, 8, 9>, strings that have been selected as second strings are ST<3, 4, 5, 10, 11, 12, 13>, strings that have been selected as third strings are ST<3, 4, 5, 14, 15, 16, 1>, some strings that overlap each other between the first string and the second string are ST<3, 4, 5>, strings that do not overlap each other between the first string and the second string are ST<6, 7, 8, 9 or 10, 11, 12, 13>, some strings that overlap each other between the first string and the third string are ST<3, 4, 5>, strings that do not overlap each other between the first string and the third string are ST<6, 7, 8, 9 or 14, 15, 16, 1>, some strings that overlap each other between the second string and the third string are ST<3, 4, 5>, and strings that do not overlap each other between the second string and the third string are ST<10, 11, 12, 13 or 14, 15, 16, 1>.

In contrast, when the physical location of the string SEL_ST that has been selected as the read target is No. 10 (ST10), it may be seen that strings that have been selected as first strings are ST<11, 12, 13, 14, 15, 16, 1>, strings that have been selected as second strings are ST<11, 12, 13, 2, 3, 4, 5>, strings that have been selected as third strings are ST<11, 12, 13, 6, 7, 8, 9>, some strings that overlap each other between the first string and the second string are ST<11, 12, 13>, strings that do not overlap each other between the first string and the second string are ST<14, 15, 16, 1 or 2, 3, 4, 5>, some strings that overlap each other between the first string and the third string are ST<11, 12, 13>, strings that do not overlap each other between the first string and the third string are ST<14, 15, 16, 1 or 6, 7, 8, 9>, some strings that overlap each other between the second string and the third string are ST<11, 12, 13>, and strings that do not overlap each other between the second string and the third string are ST<2, 3, 4, 5 or 6, 7, 8, 9>.

That is, it may be seen that strings that overlap each other between the first to third strings are changed into one of ST<3, 4, 5> and ST<11, 12, 13> depending on whether the physical location of the selected string SEL_ST is the No. 2 (ST2) or the No. 10 (ST10). Furthermore, it may be seen that whether strings that do not overlap between the first to third strings will be selected among ST<6, 7, 8, 9, 10, 11, 12, 13, 14, 15, 16, 1> or ST<14, 15, 16, 1, 2, 3, 4, 5, 6, 7, 8, 9> is determined depending on whether the physical location of the selected string SEL_ST is the No. 2 (ST2) or the No. 10 (ST10).

In the aforementioned embodiment, in the state in which the first logical page LSB, the second logical page CSB, and the third logical page MSB correspond to the selected physical page SEL_PY_PG, the contents that have been described with respect to the case in which the physical location of the string SEL_ST that has been selected as the read target is the No. 2 (ST2) and the contents that have been described with respect to the case in which the physical location of the string SEL_ST that has been selected as the read target is the No. 10 (ST10) may also be identically applied to each of cases in which the physical locations of the selected strings SEL_ST are the Nos. 1, 3, 4, 5, 6, 7, 8, 9, 11, 12, 13, 14, 15, and 16 strings (ST<1, 3, 4, 5, 6, 7, 8, 9, 11, 12, 13, 14, 15, 16>). Accordingly, for the detailed contents of the strings ST<1, 3, 4, 5, 6, 7, 8, 9, 11, 12, 13, 14, 15, 16>, reference may be made to FIG. 4C.

### In the Case of a Quad Level Cell

Referring to FIGS. 2D, 3D, and 4D, if a selected memory cell SEL_CELL that is included in a selected physical page SEL_PY_PG is a quad level cell in which 4-bit data is stored, that is, if a first logical page LSB, a second logical page CSB1, a third logical page CSB2, and a fourth logical page MSB correspond to the selected physical page SEL_PY_PG, it may be seen that a method of controlling a channel-initializing operation in a read operation for the first logical page LSB, a method of controlling a channel-initializing operation in a read operation for the second logical page CSB1, a method of controlling a channel-initializing operation in a read operation for the third logical page CSB2, and a method of controlling a channel-initializing operation in a read operation for the fourth logical page MSB are different.

Specifically, if the first logical page LSB, the second logical page CSB1, the third logical page CSB2, and the fourth logical page MSB correspond to a physical page SEL_PY_PG that has been selected by a selected word line SEL_WL, the multiple bit lines BL<1:m>, and a selected string SEL_ST, the control unit 202 may select L first strings of (K−1) unselected strings UNSEL_ST except the selected string SEL_ST, among K strings, L second strings some of which overlap the first strings and the others of which do not overlap the first strings, L third strings some of which overlap each of the first and second strings and the others of which do not overlap each of the first and second strings, and L fourth strings some of which overlap each of the first to third strings and the others of which do not overlap each of the first to third strings. In this case, K may be a natural number equal to or greater than 2, and L may be a natural number less than K−1.

Furthermore, in the read operation for the first logical page LSB, the control unit 202 may perform a channel-initializing operation on one selected string SEL_ST, among the K strings, and the L first strings. That is, in the channel-initializing operation that is included in the read operation for the first logical page LSB, the control unit 202 may discharge the channel film of the one selected string SEL_ST, among the K strings, by connecting the channel film to a ground voltage stage, may discharge the channel films of the L first strings, among the (K−1) unselected strings UNSEL_ST, by connecting the channel films to the ground voltage stage, and may isolate, from the ground voltage stage, the channel films of the remaining unselected strings except the L first strings, among the (K−1) unselected strings UNSEL_ST.

Furthermore, in the read operation for the second logical page CSB1, the control unit 202 may perform a channel-initializing operation on one selected string SEL_ST, among the K strings, and the L second strings. That is, in the channel-initializing operation that is included in the read operation for the second logical page CSB1, the control unit 202 may discharge the channel film of the one selected string SEL_ST, among the K strings, by connecting the channel film to the ground voltage stage, may discharge the channel films of the L second strings, among the (K−1) unselected strings UNSEL_ST, by connecting the channel films to the ground voltage stage, and may isolate, from the ground voltage stage, the channel films of the remaining unselected strings except the L second strings, among the (K−1) unselected strings UNSEL_ST.

Furthermore, in the read operation for the third logical page CSB2, the control unit 202 may perform a channel-initializing operation on one selected string SEL_ST, among the K strings, and the L third strings. That is, in the channel-initializing operation that is included in the read operation for the third logical page CSB2, the control unit 202 may discharge the channel film of the one selected string SEL_ST, among the K strings, by connecting the channel film to the ground voltage stage, may discharge the channel films of the L third strings, among the (K−1) unselected strings UNSEL_ST, by connecting the channel films to the ground voltage stage, and may isolate, from the ground voltage stage, the channel films of the remaining unselected strings except the L third strings, among the (K−1) unselected strings UNSEL_ST.

Furthermore, in the read operation for the fourth logical page MSB, the control unit 202 may perform a channel-initializing operation on one selected string SEL_ST, among the K strings, and the L fourth strings. That is, in the channel-initializing operation that is included in the read operation for the fourth logical page MSB, the control unit 202 may discharge the channel film of the one selected string SEL_ST, among the K strings, by connecting the channel film to the ground voltage stage, may discharge the channel films of the L fourth strings, among the (K−1) unselected strings UNSEL_ST, by connecting the channel films to the ground voltage stage, and may isolate, from the ground voltage stage, the channel films of the remaining unselected strings except the L fourth strings, among the (K−1) unselected strings UNSEL_ST.

In this case, it may be seen that the number of each of the first to fourth strings the channels of which are initialized through the channel-initializing operation is less than the number of (K−1) unselected strings UNSEL_ST because L is the natural number less than K−1.

Furthermore, the control unit 202 may set a number “L+1” as a number “K/2 or more”. That is, in one channel-initializing operation that is performed on one of the first to fourth strings, the control unit 202 may initialize a channel corresponding to half (K/2) or more of the K strings.

Furthermore, if the first logical page LSB, the second logical page CSB1, the third logical page CSB2, and the fourth logical page MSB correspond to the selected physical page SEL_PY_PG, when a channel-initializing operation is performed on each of the first to fourth strings once, that is, when the four channel-initializing operations are performed on the first to fourth strings, the control unit 202 may properly select the first to fourth strings so that at least one channel-initializing operation is performed on each of the K strings. That is, the control unit 202 may properly select some strings that overlap each other between the first to fourth strings and the other strings that do not overlap each other between the first to fourth strings, so that at least one channel-initializing operation is performed on each of the K strings when the channel-initializing operation is performed on each of the first to fourth strings once.

Furthermore, the control unit 202 may adjust a number of the strings that overlap each other between the first to fourth strings, based on the physical location of the selected string SEL_ST among the K strings. Furthermore, the control unit 202 may adjust the other strings that do not overlap each other between the first to fourth strings, based on the physical location of the selected string SEL_ST among the K strings.

In summary, it may be seen that a difference between the method of controlling the channel-initializing operation in the read operation for the first logical page LSB and the method of controlling the channel-initializing operation in the read operation for the second logical page MSB, which have been disclosed with reference to FIGS. 2B, 3B, and 4B, may be extended and applied as a difference between a method of controlling a channel-initializing operation in a read operation for the first logical page LSB and a method of controlling a channel-initializing operation in a read operation for the second logical page CSB1, a difference between the method of controlling the channel-initializing operation in the read operation for the second logical page CSB1 and a method of controlling a channel-initializing operation in a read operation for the third logical page CSB2, a difference between the method of controlling the channel-initializing operation in the read operation for the third logical page CSB2 and a method of controlling a channel-initializing operation in a read operation for the fourth logical page MSB, a difference between the method of controlling the channel-initializing operation in the read operation for the first logical page LSB and the method of controlling the channel-initializing operation in the read operation for the third logical page CSB2, a difference between the method of controlling the channel-initializing operation in the read operation for the first logical page LSB and the method of controlling the channel-initializing operation in the read operation for the fourth logical page MSB, and a difference between the method of controlling the channel-initializing operation in the read operation for the second logical page CSB1 and the method of controlling the channel-initializing operation in the read operation for the fourth logical page MSB, which have been disclosed with reference to FIGS. 2D, 3D, and 4D.

FIG. 2D may illustrate a table in the state in which selected memory cells SEL_CELL configuring a selected physical page SEL_PY_PG are quad level cells in each of which 4-bit data is stored, a change in the physical location of a string SEL_ST that has been selected as a read target, among the six strings ST<1:6>, is divided as a column and the four logical pages LSB, CSB1, CSB2, and MSB corresponding to the physical page SEL_PY_PG that has been selected as a read target are divided as rows. Referring to a table in FIG. 2D, it may be seen which string is selected as a target for a channel-initializing operation based on a change in the physical location of the selected string SEL_ST and a change in the four logical pages LSB, CSB1, CSB2, and MSB in the state in which K has been set to 6 and L has been set to 2. A detailed meaning of the table disclosed in FIG. 2D may be understood with reference to the descriptions related to FIGS. 2B and 2C. Accordingly, a detailed description of FIG. 2D is omitted hereinafter.

Furthermore, FIG. 3D may illustrate a table in the state in which selected memory cells SEL_CELL configuring a selected physical page SEL_PY_PG are quad level cells in each of which 4-bit data is stored, a change in the physical location of a string SEL_ST that has been selected as a read target, among the eight strings ST<1:8>, is divided as a column and the four logical pages LSB, CSB1, CSB2, and MSB corresponding to the physical page SEL_PY_PG that has been selected as a read target are divided as rows. Referring to a table in FIG. 3D, it may be seen which string is selected as a target for a channel-initializing operation based on a change in the physical location of the selected string SEL_ST and a change in the four logical pages LSB, CSB1, CSB2, and MSB in the state in which K has been set to 8 and L has been set to 4. A detailed meaning of the table disclosed in FIG. 3D may be understood with reference to the descriptions related to FIGS. 3B and 3C. Accordingly, a detailed description of FIG. 3D is omitted hereinafter.

Furthermore, FIG. 4D may illustrate a table in the state in which selected memory cells SEL_CELL configuring a selected physical page SEL_PY_PG are quad level cells in each of which 4-bit data is stored, a change in the physical location of a string SEL_ST that has been selected as a read target, among the sixteen strings ST<1:16>, is divided as a row, and the four logical pages LSB, CSB1, CSB2, and MSB corresponding to the physical page SEL_PY_PG that has been selected as a read target are divided as columns. Referring to a table in FIG. 4D, it may be seen which string is selected as a target for a channel-initializing operation based on a change in the physical location of the selected string SEL_ST and a change in the four logical pages LSB, CSB1, CSB2, and MSB in the state in which K has been set to 16 and L has been set to 9. A detailed meaning of the table disclosed in FIG. 4D may be understood with reference to the descriptions related to FIGS. 4B and 4C. Accordingly, a detailed description of FIG. 4D is omitted hereinafter.

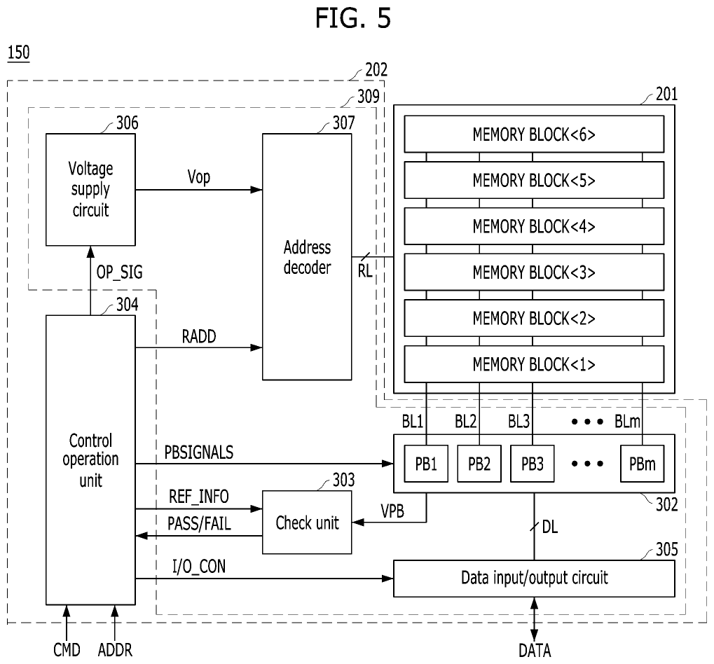

FIG. 5 is a diagram for describing a detailed configuration of the memory device 150 according to an embodiment of the present disclosure, which is disclosed in FIG. 1.

Referring to FIG. 5, the memory device 150 may include the memory cell array 201 and the control unit 202. The control unit 202 may include a control circuit unit (i.e., peripheral circuits) 309 and a control operation unit (i.e., control logic) 304. Furthermore, the control circuit unit 309 may include a page buffer unit 302, a check unit 303, a data input/output circuit 305, a voltage supply circuit 306, and an address decoder 307.

The memory cell array 201 may include a plurality of memory blocks MEMORY BLOCK<1:6>. The plurality of memory blocks MEMORY BLOCK<1:6> may be connected to an address decoder 307 through a row line RL. The plurality of memory blocks MEMORY BLOCK<1:6> may be connected to the page buffer unit 302 through bit lines BL1 to BLm. Each of the memory blocks MEMORY BLOCK<1:6> may include a plurality of memory cells.

Each of multiple memory blocks MEMORY BLOCK<1:6> may include a 3-D structure. That is, each of the multiple memory blocks MEMORY BLOCK<1:6> may include the multiple memory cells that are arranged as the 3-D structure in the +X direction, the +Y direction, and the +Z direction, which have been described with reference to FIG. 1.

The row line RL may include at least one source selection line, a plurality of word lines and at least one drain selection line.

The control circuit unit 309 may be configured to perform a program, read or erase operation on a selected region of the memory cell array 201. The control circuit unit 309 may drive the memory cell array 201. For example, the control circuit unit 309 may apply various operating voltages to the row line RL and the bit lines BL1 to BLm, or discharge the applied voltages.

The control circuit unit 309 may perform a read operation on the selected physical page SEL_PY_PG (refer to FIG. 1) under the control of the control operation unit 304. For example, as described with reference to FIGS. 2B, 3B, and 4B, if the first logical page LSB and the second logical page MSB correspond to the selected physical page SEL_PY_PG, the control circuit unit 309 may independently perform a read operation on each of the first logical page LSB and the second logical page MSB under the control of the control operation unit 304.

The address decoder 307 among the control circuit unit 309 may be connected to the memory cell array 201 through the row line RL. The row line RL may include the drain selection line, the word lines, the source selection line and a common source line.

The address decoder 307 may be configured to operate in response to the control of the control operation unit 304. The address decoder 307 may receive an address RADD from the control operation unit 304.

The address decoder 307 may be configured to decode a block address of the received address RADD. The address decoder 307 may select at least one memory block among the memory blocks MEMORY BLOCK<1:6> according to the decoded block address. The address decoder 307 may be configured to decode a row address of the received address RADD. The address decoder 307 may select at least one word line among word lines of the selected memory block according to the decoded row address. The address decoder 307 may apply operating voltages Vop, which are supplied from the voltage supply circuit 306, to the selected word line.

The voltage supply circuit 306 among the control circuit unit 309 may be configured to generate a plurality of operating voltages Vop by using an external power supply voltage. The voltage supply circuit 306 may operate in response to the control of the control operation unit 304.

In an embodiment, the voltage supply circuit 306 may regulate the external power supply voltage, and generate an internal power supply voltage.

In an embodiment, the voltage supply circuit 306 may generate the plurality of operating voltages Vop by using the external power supply voltage or the internal power supply voltage. For example, the voltage supply circuit 306 may generate a plurality of erase voltages, a plurality of program voltages, a plurality of pass voltages, a plurality of selective read voltages and a plurality of unselective read voltages.

The voltage supply circuit 306 may include a plurality of pumping capacitors, which receive the internal power supply voltage, to generate the plurality of operating voltages Vop having various voltage levels, and generate the plurality of operating voltages Vop by selectively activating the plurality of pumping capacitors in response to the control of the control operation unit 304.

The generated operating voltages Vop may be supplied to the memory cell array 201 by the address decoder 307. For example, the voltage supply circuit 306 may adjust the level and supply time of each of the operation voltages Vop in response to the operation signal OP_SIG. For example, the voltage supply circuit 306 may generate, as the operation voltages Vop, a program voltage, a pass voltage, a verification voltage, a read voltage, an erase voltage, a turn-on voltage, a turn-off voltage, and a source line voltage, and may supply the operation voltages Vop to the address decoder 307. For example, after the start of a read operation, the voltage supply circuit 306 may generate, as the operation voltages Vop, the read voltage, the pass voltage, the turn-on voltage, the turn-off voltage, and the ground voltage in response to the operation signal OP_SIG, and may supply the generated operation voltages Vop to the address decoder 307. The read voltage may be a voltage that is supplied to a selected word line. The pass voltage may be a voltage that is supplied to unselected word lines. The turn-on voltage and the turn-off voltage may be voltages that are applied to a drain selection line or a source selection line. The ground voltage may be a voltage that is applied to a source line, and may be 0 V. The voltage supply circuit 306 may adjust the supply time of each of the operation voltages Vop in response to the operation signal

OP_SIG. For example, the voltage supply circuit 306 may adjust the output time of each of the read voltage, the pass voltage, the turn-on voltage, the turn-off voltage, and the ground voltage in response to the operation signal OP_SIG, and may output the read voltage, the pass voltage, the turn-on voltage, the turn-off voltage, and the ground voltage based on the adjusted times, respectively.

The page buffer unit 302 may include a plurality of page buffers PB1 to PBm. The plurality of page buffers PB1 to PBm may be connected to the memory cell array 201 through the plurality of bit lines BL1 to BLm, respectively. The plurality of page buffers PB1 to PBm may operate in response to the control of the control operation unit 304.

The plurality of page buffers PB1 to PBm may communicate data DATA with the data input/output circuit 157. During the program operation, the plurality of page buffers PB1 to PBm may receive the data DATA to be stored, through the data input/output circuit 157 and a data line DL.

After the start of a program operation, the multiple page buffers PB1 to PBm may store data DATA that is received from the outside through the data input/output circuit 305, and may transmit a program permission voltage or a program inhibition voltage to the bit lines BL1 to BLm in response to the stored data DATA. For example, the program permission voltage may be 0 V, and the program inhibition voltage may be a power supply voltage.

After the start of a read operation, the multiple page buffers PB1 to PBm may sense data DATA based on a voltage or current of the bit lines BL1 to BLm, which is determined based on threshold voltages of the memory cells of a selected page, and may transmit the sensed data DATA to the data input/output circuit 305 through the data lines DL.

After the start of an erase operation, the multiple page buffers PB1 to PBm may make the bit lines BL1 to BLm float or may apply a voltage of 0 V to the bit lines BL1 to BLm.

The data input/output circuit 305 may include a plurality of input/output buffers (not illustrated) that receive the data DATA inputted thereto. During the program operation, the data input/output circuit 305 may receive the data DATA to be stored from an external. The data input/output circuit 305 may output the data DATA, which is transmitted from the plurality of page buffers PB1 to PBm included in the page buffer unit 302, to the external during the read operation.

The check unit 303 of the control circuit unit 309 may generate a reference current in response to a reference information (REF_INFO) signal that is generated by the control operation unit 304 after the start of a read operation or a verification operation, may compare a sensing voltage VPB that is received from the page buffer group 123 and a reference voltage that is generated from the reference current, and may output a pass signal PASS or a fail signal FAIL to the control operation unit 304. For example, when a level of the sensing voltage VPB is higher than or equal to a level of the reference voltage, the check unit 303 may output the pass signal PASS to the control operation unit 304. When the level of the sensing voltage VPB is lower than the level of the reference voltage, the check unit 303 may output the fail signal FAIL to the control operation unit 304.

The control operation unit 304 may be connected to the address decoder 307, the voltage supply circuit 306, the page buffer unit 302, the data input/output circuit 305, and the check unit 303 that are included in the control circuit unit 309. The control operation unit 304 may be configured to control an overall operation of the memory device 150. The control operation unit 304 may operate in response to a command CMD from an external device.

The control operation unit 304 may control the control circuit unit 309 by generating various signals in response to the command CMD and an address ADDR. For example, the control operation unit 304 may generate an operation signal OPSIG, an address RADD, a read and write control signal PBSIGNALS, and the reference information REF_INFO, in response to the command CMD and the address ADDR. The control operation unit 304 may output the operation signal OPSIG to the voltage supply circuit 306, may output the address RADD to the address decoder 307, may output the read and write control signal PBSIGNALS to the page buffer unit 302, and may output the reference information REF_INFO to the check unit 303. Furthermore, the control operation unit 304 may determine whether a verification operation has passed or failed in response to the pass or fail signal PASS/FAIL that is output by the check unit 303.

After the start of a read operation, the control operation unit 304 may control the read operation of reading data from a selected region of the memory cell array 201. That is, the control operation unit 304 may read data that has been stored in selected memory cells SEL_CELL configuring a physical page SEL_PY_PG that has been selected by the selected word line SEL_WL, the multiple bit lines BL<1:m>, and the selected string SEL_ST. In particular, when the selected memory cells SEL_CELL configuring the selected physical page SEL_PY_PG are memory cells in each of which 2-bit or more data is stored, the control operation unit 304 may adjust a method of controlling a channel-initializing operation in a read operation for the selected physical page SEL_PY_PG, based on the bit data read from the 2-bit or more data stored in the selected memory cells SEL_CELL. For example, if a first logical page LSB and a second logical page MSB correspond to the selected physical page SEL_PY_PG, the control operation unit 304 may control a channel-initializing operation that is performed on strings in a read operation for the first logical page LSB and a channel-initializing operation that is performed on strings in a read operation for the second logical page MSB so that some of the strings in the read operation for the first logical page LSB and the strings in the read operation for the second logical page MSB overlap each other and some other of the strings do not overlap each other. As another example, if a first logical page LSB, a second logical page CSB, and a third logical page MSB correspond to the selected physical page SEL_PY_PG, the control operation unit 304 may control a channel-initializing operation that is performed on strings in a read operation for the first logical page LSB, a channel-initializing operation that is performed on strings in a read operation for the second logical page CSB, and a channel-initializing operation that is performed on strings in a read operation for the third logical page MSB so that some of the strings in the read operation for the first logical page LSB, the strings in the read operation for the second logical page CSB, and the strings in the read operation for the third logical page MSB overlap each other and some other of the strings do not overlap each other. As still another example, if a first logical page LSB, a second logical page CSB1, a third logical page CSB2, and a fourth logical page MSB correspond to the selected physical page SEL_PY_PG, the control operation unit 304 may control a channel-initializing operation that is performed on strings in a read operation for the first logical page LSB, a channel-initializing operation that is performed on strings in a read operation for the second logical page CSB1, a channel-initializing operation that is performed on strings in a read operation for the third logical page CSB2, and a channel-initializing operation that is performed on strings in a read operation for the fourth logical page MSB so that some of the strings in the read operation for the first logical page LSB, the strings in the read operation for the second logical page CSB1, the strings in the read operation for the third logical page CSB2, and the strings in the read operation for the fourth logical page MSB overlap each other and some other of the strings do not overlap each other.

FIG. 6 is a diagram for describing a circuit configuration of a string in the memory cell array including the 3-D structure in which six strings are connected to one bit line, which is disclosed in FIGS. 1 and 2A according to an embodiment of the present disclosure.

First, in the description related to FIGS. 1 and 2A, K is 6. Accordingly, in the following description, K is 6.

Referring to FIG. 6 along with FIGS. 1 and 2A, the six strings ST<1:6> may be connected between the multiple bit lines BL1 to BLm and a source line SL. The six strings ST<1:6> may include source selection transistors SST, memory cells F1 to Fn (n is a positive integer), and drain selection transistors DST that are connected in series between the source line SL and the multiple bit lines BL1 to BLm.

Gates of the source selection transistors SST that are included in different six strings ST<1:6> may be connected to a first or second source selection line SSL1 or SSL2. Source selection transistors that are adjacent to each other in the X direction, among the source selection transistors SST, may be connected to the same source selection line. Some of source selection transistors that are adjacent to each other in the Y direction, among the source selection transistors SST, may be connected to different source selection lines. For example, first to third source selection transistors, among source selection transistors SST that are arranged in the Y direction, may be connected to the first source selection line SSL1. Fourth to sixth source selection transistors, among the source selection transistors SST that are arranged in the Y direction, may be connected to the second source selection line SSL2.

Gates of the memory cells F1 to Fn that are included in different six strings ST<1:6> may be connected to the word lines WL1 to WLn.

Gates of the drain selection transistors DST that are included in different six strings ST<1:6> may be connected to one of the first to sixth drain selection lines DSL1 to DSL6. Gates of drain selection transistors that are arranged in the X direction, among the drain selection transistors DST, may be connected to the same drain selection line in common, but gates of drain selection transistors that are arranged in the Y direction, among the drain selection transistors DST, may be connected to different drain selection lines. For example, if the drain selection transistors DST are sequentially arranged in the Y direction, first drain selection transistors may be connected to a first drain selection line DSL1, second drain selection transistors may be connected to a second drain selection line DSL2, third drain selection transistors may be connected to a third drain selection line DSL3, fourth drain selection transistors may be connected to a fourth drain selection line DSL4, fifth drain selection transistors may be connected to a fifth drain selection line DSL5, and sixth drain selection transistors may be connected to a sixth drain selection line DSL6.

After the start of a program or read operation, one string, among the six strings ST<1:6> that are connected to a selected drain selection line within a selected memory block, may become a selected string. Sixteen strings that are connected to unselected drain selection lines may become unselected strings. For example, when the turn-on voltage having a positive voltage is applied to the first drain selection line DSL1 and the turn-off voltage of 0 V is applied to the second to sixth drain selection lines DSL2 to DSL6, the first drain selection line DSL1 may become a selected drain selection line, and the second to sixth drain selection lines DSL2 to DSL6 may become unselected drain selection lines. Accordingly, a No. 1 string ST1 that is connected to the first drain selection line DSL1 may become a selected string, and five strings ST<2:6> that are connected to the second to sixth drain selection lines DSL2 to DSL6 may become unselected strings.

After the start of a program or read operation, the first source selection line SSL1 that is connected to a selected string, among the first and second source selection lines SSL1 and SSL2, may become a selected source selection line. The second source selection line SSL2 that is connected to an unselected string, among the first and second source selection lines SSL1 and SSL2, may become an unselected source selection line. Accordingly, some of the selected strings and the unselected strings may be connected to the selected source selection line, and only the unselected strings may be connected to the unselected source selection line.

Memory cells that are connected to the same word line may constitute one page PG. In this case, the page may mean a physical page. For example, memory cells that are arranged in the X direction, among first memory cells F1 that are connected to the first word line WL1, may constitute one page PG. Accordingly, a plurality of pages may be connected to each of the multiple word lines WL1 to WLn.

Since a program or read operation is performed on a selected page, a selected page, among pages that are connected to the same word line, may be determined by a selected drain selection line. For example, after the start of a read operation, if the first word line WL1 is a selected word line and the first drain selection line DSL1 is a selected drain selection line, selected memory cells configuring a string connected to the first drain selection line DSL1, among memory cells that are connected to the first word line WL1, may constitute a selected page, and the remaining unselected memory cells may constitute unselected pages.

Although one source selection transistor SST and one drain selection transistor DST have been illustrated as being included in one string ST in the drawing, multiple source selection transistors SST and multiple drain selection transistors DST may be included in one string ST depending on a memory device. Furthermore, dummy cells may be included between the source selection transistor SST, the memory cells F1 to Fn, and the drain selection transistor DST depending on a memory device. The dummy cells are cells that are added to improve electrical characteristics of the six strings ST<1:6>, and thus may store dummy data without storing user data, unlike the memory cells F1 to Fn.

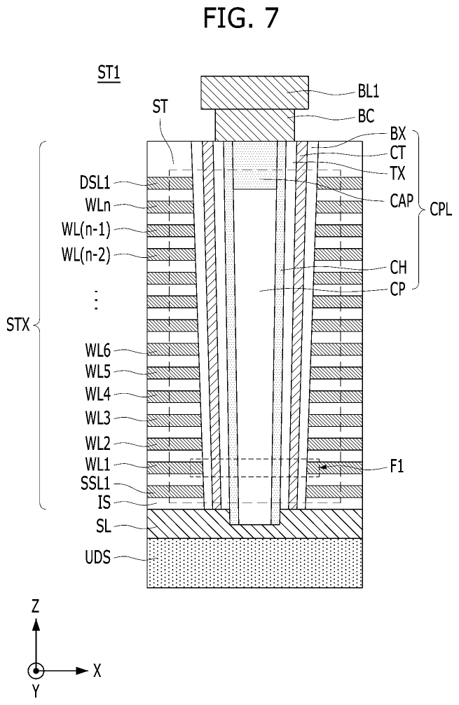

FIG. 7 is a diagram for describing a cross-sectional structure of one of the six strings illustrated in FIG. 6 according to an embodiment of the present disclosure.

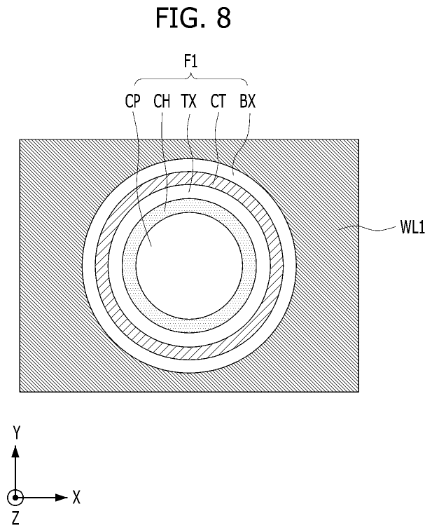

FIG. 8 is a diagram for describing a layout structure of the memory cell illustrated in FIG. 7 according to an embodiment of the present disclosure.

Referring to FIGS. 7 and 8, the No. 1 string ST1 that is connected between the first bit line BL1 and the source line SL, among the six strings illustrated in FIG. 6, is illustrated as an example.

The source line SL may be formed on a lower structure UDS, and a stack structure STK may be formed on the source line SL. The lower structure UDS may be a substrate or a peripheral circuit. The source line SL may be formed of a conductive material. For example, the source line SL may be formed of doped polysilicon. The stack structure STK may include gate lines and insulating layers IS. The gate lines may include the first source select line SSL1, the first to n-th word lines WL1 to WLn, and the first drain select line DSL1. The first source select line SSL1, the first to n-th word lines WL1 to WLn, and the first drain select line DSL1 may be formed of a conductive material. For example, the first source select line SSL1, the first to n-th word lines WL1 to WLn, and the first drain select line DSL1 may be formed of a conductive material, such as tungsten (W), molybdenum (Mo), cobalt (Co), or nickel (Ni), or a semiconductor material, such as silicon (Si) or poly silicon (Poly-Si), or may be formed of various other metal materials. The insulating layers IS may be formed of an oxide layer or a silicon oxide layer.

The string ST may be formed of a cell plug CPL that passes through the stack structure STK. For example, the string ST may include the cell plug CPL that is perpendicular to the source line SL. The cell plug CPL may include a blocking layer BX, a charge trap layer CT, a tunnel isolation layer TX, a channel layer CH, a core pillar CP, and a capping layer CAP. For example, the blocking layer BX may be formed in a cylindrical shape, passing through the stack structure STK, and may be formed of an oxide layer or a silicon oxide layer. The charge trap layer CT may be formed in a cylindrical shape along an inner wall of the blocking layer BX and may be formed of a nitride layer. The tunnel isolation layer TX may be formed in a cylindrical shape along an Inner wall of the charge trap layer CT and may be formed of an oxide layer or a silicon oxide layer. The channel layer CH may be formed in a cylindrical shape along an inner wall of the tunnel isolation layer TX and may be formed of poly silicon. The core pillar CP may be formed in a cylindrical shape, filling the interior of the channel layer CH, and may be formed of an insulating material, such as an oxide layer or a silicon oxide layer. The capping layer CAP may be formed on the core pillar CP and may be formed of a conductive material. When the capping layer CAP is formed on the core pillar CP, a height of an upper surface of the core pillar CP may be formed to be lower than a height of an upper surface of the channel layer CH, and the capping layer CAP may be formed in an area that is surrounded by the core pillar CP and the channel layer CH.

A bit line contact BC and the first bit line BL1 may be formed on the cell plug CPL. The bit line contact BC may be formed of a conductive material and may be in contact with the channel layer CH that is included in the cell plug CPL. The first bit line BL1 may be formed on the bit line contact BC and may be formed of a conductive material.

A portion of the cell plug CPL, corresponding to the same layer as the first to n-th word lines WL1 to WLn, may be the memory cells. When describing a layout of the first memory cell F1 that is connected to the first word line WL1 with reference to FIG. 6, the first memory cell F1 may be surrounded by the first word line WL1. The first memory cell F1 may include the core pillar CP that is formed in a cylindrical shape, the channel layer CH surrounding the core pillar CP, the tunnel isolation layer TX surrounding the channel layer CH, the charge trap layer CT surrounding the tunnel isolation layer TX, and the blocking layer BX surrounding the charge trap layer CT. The blocking layer BX may be formed between the charge trap layer CT and the first word line WL1 and may be used to electrically block the charge trap layer CT from the first word line WL1. The charge trap layer CT may be used to trap electrons. During the program operation, when the electrons are trapped in the charge trap layer CT, a threshold voltage of the first memory cell F1 may increase, and when the threshold voltage increases to a target voltage, the program operation of the first memory cell F1 may be completed. The tunnel isolation layer TX may electrically block the charge trap layer CT from the channel layer CH, and when a voltage difference between the first word line WL1 and the channel layer CH becomes higher than a specific level, the tunnel isolation layer TX may be used as a path through which an electron is tunneled. The channel layer CH may be used as a layer in which a channel through which carriers may move during the program or read operation is formed. In addition, the channel layer CH may be used to increase a channel voltage in order to prevent a threshold voltage of the memory cells configuring the unselected strings from being changed by the pass voltage during the read operation. Increasing the channel voltage of the unselected strings is referred to as channel boosting.

A channel boosting operation is described as follows with reference to the circuit configuration of the string disclosed in FIG. 6.

During the read operation, a second word line WL2 is selected among the first to n-th word lines WL1 to WLn and the second drain select line DSL2 is the selected drain select line among the first to fourth drain select lines DSL1 to DSL6.

Since the second word line WL2 is the selected word line, second memory cells F2 that are connected to the second word line WL2 may become selected page Sel_PG. Among the second memory cells F2, a memory cell that is connected to the second drain select line DSL2 may become a selected memory cell Sel_Cell, and the remaining second memory cells F2 may become unselected memory cells.

During the read operation, a precharge voltage Vpr may be applied to the first bit line BL1, and a ground voltage GND may be applied to the source line SL. The ground voltage GND may be a 0V voltage. A turn on voltage may be applied to the second drain select line DSL2, which is the selected drain select line, and a turn off voltage may be applied to the first, third, and fourth drain select lines DSL1, DSL3, DSL4, DSL5 and DSL6, which are the unselected drain select lines after the turn on voltage is applied to the first, third, and fourth drain select lines DSL1, DSL3, DSL4, DSL5 and DSL6. Accordingly, a drain select transistor that is connected to the second drain select line DSL2 may be turned on (ON), and drain select transistors that are connected to the first, third, and fourth drain select lines DSL1, DSL3, DSL4, DSL5 and DSL6 may be turned on and then turned off again (OFF). A read voltage Vread may be applied to the second word line WL2, which is the selected word line, and a pass voltage Vpass that is higher than the read voltage Vread may be applied to the first and third to n-th word lines WL1 and WL3 to WLn, which are the unselected word lines. The turn on voltage may be applied to the first source select line SSL1 that is connected to the selected string, including the selected memory cell Sel_Cell, and the turn off voltage may be applied to the second source select line SSL2 that is connected to the unselected strings, including only the unselected memory cells. Therefore, source select transistors that are connected to the first source select line SSL1 may be turned on (ON), and source select transistors that are connected to the second source select line SSL2 may be turned off (OFF). In strings 71 in which a drain select transistor and a source select transistor of both unselected strings are turned off, a channel boosting may occur due to a coupling between a channel to which the precharge voltage Vpr is applied and the unselected word lines to which the pass voltage Vpass is applied.

When the channel boosting occurs in the unselected strings, hot carrier injection may occur due to a voltage difference between the read voltage Vread that is applied to the selected word line and a channel of the unselected strings. The hot carrier injection is a phenomenon in which an electron is input to the unselected memory cells. In particular, when an electron is trapped in the tunnel isolation layer TX of FIG. 7 of the memory cell due to the hot carrier injection, removing the electron that is trapped in the tunnel isolation layer TX through the program or erase operation may be difficult. As described above, hot carrier injection may degrade the reliability of program and read operations of memory cells. Accordingly, in the present disclosure, in order to prevent the occurrence of the hot carrier injection, a channel may be discharged through a channel-initializing operation. For example, when the source line to which a ground voltage is applied is connected to the channel film of an unselected string, the channel film may be discharged. That is, by electrically connecting the channel film to the bit line and the source line, a current may flow into the channel film between the bit line and the source line, so that the channel film may be discharged. When the channel films of the unselected string are discharged, hot carrier injection can be prevented because the electric potential of the channel film is lowered.

It will be evident to a person having ordinary knowledge in the art to which the present disclosure pertains that the present disclosure described above is not limited by the aforementioned embodiments and the accompanying drawings and may be substituted, modified, and changed in various ways without departing from the technical spirit of the present disclosure and the following claims. Furthermore, the embodiments may be combined to form additional embodiments.

For example, the locations and types of the logic gates and the transistors illustrated in the aforementioned embodiments have to be differently implemented depending on the polarity of an input signal.

What is claimed is:

1. A memory device comprising:
a memory cell array comprising multiple memory cells that are connected between multiple word lines, multiple bit lines, and K strings; and
a controller configured to:
perform, in a read operation on a first logical page of a selected physical page corresponding to a selected word line, the multiple bit lines and a selected string, a first channel-initializing operation on the selected string and first strings among unselected strings, and
perform, in a read operation on a second logical page of the selected physical page, a second channel-initializing operation on the selected string and second strings among the unselected strings, the first and second strings partially overlapping each other, wherein K is a natural number equal to or greater than 2.

2. The memory device of claim 1, wherein the controller comprises:
control circuits configured to perform the read operation on each of the first and second logical pages; and
a control logic configured to control the control circuits to perform the first and second channel-initializing operations.

3. The memory device of claim 2, wherein the control logic is configured to adjust, based on a physical location of the selected string, a number of the first and second strings that overlap each other.

4. The memory device of claim 1,
wherein the selected and unselected strings belong to K number of strings, and
wherein the controller is further configured to select the first and second strings so that any of the first and second channel-initializing operations is performed at least once on each of the K strings when each of the first and second channel-initializing operations is performed once.

5. The memory device of claim 1,
wherein the first and second strings are respectively L number of strings and the selected and unselected strings belong to K number of strings, and
wherein a number “L+1” is a number “K/2” or more.

6. The memory device of claim 1, wherein the first and second logical pages respectively correspond to each bit of 2-bit data stored in each of memory cells configuring the selected physical page.

7. The memory device of claim 1, wherein in an interval for the first channel-initializing operation, the controller is configured to discharge channel films of the selected string and the first strings by connecting the channel films to a ground voltage stage while isolating, from the ground voltage stage, channel films of remaining unselected strings except the first strings.

8. The memory device of claim 1, wherein in an interval for the second channel-initializing operation, the controller is configured to discharge channel films of the selected string and the second strings by connecting the channel films to a ground voltage stage while isolating, from the ground voltage stage, channel films of remaining unselected strings except the second strings.

9. An operating method of a memory device, comprising:
a selection operation of selecting first and second strings from unselected strings if first and second logical pages correspond to a selected physical page corresponding to a selected word line, multiple bit lines and a selected string, the first and second strings partially overlapping each other;
a first initialization operation of performing a channel-initializing operation on the selected string and the first strings in a read operation on the first logical page; and
a second initialization operation of performing a channel-initializing operation on the selected string and the second strings in a read operation for the second logical page.

10. The operating method of claim 9, wherein the selection operation includes adjusting, based on a physical location of the selected string, a number of the first and second strings that overlap each other.

11. The operating method of claim 9,
wherein the selected and unselected strings belong to K number of strings,
wherein the selection step includes selecting the first and second strings so that the channel-initializing operation is performed at least once on each of the K strings when each of the first and second initialization steps is performed once, and
wherein K is a natural number equal to or greater than 2.

12. The operating method of claim 9,
wherein the first and second strings are respectively L number of strings and the selected and unselected strings belong to K number of strings, and
wherein a number “L+1” is a number “K/2” or more.

13. The operating method of claim 9, wherein the first and second logical pages respectively correspond to each bit of 2-bit data stored in each of memory cells configuring the selected physical page.

14. The operating method of claim 9, wherein the first initialization operation comprises:
discharging channel films of the selected string and the first strings by connecting the channel films to a ground voltage stage in an interval for the channel-initializing operation, and
isolating, from the ground voltage stage, channel films of remaining unselected strings except the first strings in the interval for the channel-initializing operation.

15. The operating method of claim 9, wherein the second initialization operation comprises:
discharging channel films of the selected string and the second strings by connecting the channel films to a ground voltage stage in an interval for the channel-initializing operation, and
isolating, from the ground voltage stage, channel films of remaining unselected strings except the second strings, among the (K−1) unselected strings in the interval for the channel-initializing operation.

16. An operating method of a memory device including memory cell strings configuring at least a physical page, the operating method comprising:
selecting one from the memory cell strings;
determining first to third groups of unselected ones from the memory cell strings, the third group being an intersection of the first and second groups;
performing a channel-initializing operation on the selected string and the first group during a read operation on a first logical page of the physical page; and
performing the channel-initializing operation on the selected string and the second group during a read operation on a second logical page of the physical page,
wherein the determining includes adjusting, based on a physical location of the selected string, a number of the unselected memory cell strings belonging to the third group.
